(19) United States
(12) Patent Application Publication
(10) Pub. No.: US 2026/0081125 A1
(43) Pub. Date: Mar. 19, 2026

(54) MULTI-SENSOR DETERMINATION OF A STATE OF SEMICONDUCTOR EQUIPMENT

(71) Applicant: Lam Research Corporation, Fremont, CA (US)

(72) Inventors: Kapil Sawlani, West Linn, OR (US); Paul Franzen, West Linn, OR (US); Miguel Benjamin Vasquez, Portland, OR (US); Benjamin Tong Yee, Portland, OR (US); Paul Konkola, West Linn, OR (US); John Valley, Tualatin, OR (US)

(21) Appl. No.: 19/110,031

(22) PCT Filed: Aug. 29, 2023
(86) PCT No.: PCT/US2023/031458

§ 371 Date: Mar. 7, 2025

Related U.S. Application Data
(60) Provisional application No. 63/375,025, filed on Sep. 8, 2022.

(51) Int. Cl. H01J 37/32; G01N 21/73; G05B 13/02

(52) U.S. Cl. CPC H01J 37/3299; G01N 21/73; G05B 13/0265; H10P 72/0604; H01J 2237/2445; H01J 2237/24585

(57) ABSTRACT

Methods and apparatus for multi-sensor determination of a state of semiconductor equipment are provided In some embodiments disclosed herein, semiconductor manufacturing equipment may include: a plurality of sensors comprising one or more spatial sensors, one or more spectral sensors, and one or more temporal sensors disposed about the semiconductor manufacturing equipment; and a controller communicatively coupled to the plurality of sensors, the controller configured to cause: determining a set of signals, from the plurality of sensors, to monitor during a process to be performed by the semiconductor manufacturing equipment; during the process, obtaining measurements associated with the set of signals from the plurality of sensors; and determining an indication of a state of the semiconductor manufacturing equipment based on a combination of data generated from the measurements associated with the set of signals.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Sensors associated with semiconductor equipment, such as multi-station fabrication tools (including, e.g., multi-station process chambers), typically perform one specialized type of task. For example, automatic infrared endpoint detection (IR-EPD) is used for endpoint detection during cleaning for all stations (e.g., all four stations of a multi-station process chamber). Some sensors handle a specific class of problems. For example, one or more cameras are used in isolation to study characteristics of plasma. In addition, there may be ex-situ measurements performed with metrology tools, each of which can provide an indication of a specific state or characteristic relating to the equipment (film thickness, resistivity, refractive index (RI), stress, etc.). As a whole, sensors or metrology tools are typically employed for specific task or specific class of problems.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

In one aspect of the present disclosure, a manufacturing system is disclosed. In some embodiments, the manufacturing system includes: semiconductor manufacturing equipment; a plurality of sensors comprising one or more spatial sensors, one or more spectral sensors, and one or more temporal sensors disposed about the semiconductor manufacturing equipment; and a controller communicatively coupled to the plurality of sensors, the controller configured to cause: determining a set of signals, from the plurality of sensors, to monitor during a process to be performed by the semiconductor manufacturing equipment; during the process, obtaining measurements associated with the set of signals from the plurality of sensors; and determining an indication of a state of the semiconductor manufacturing equipment based on a combination of data generated from the measurements associated with the set of signals.

In another aspect of the present disclosure, a method for multi-sensor determination of a state of semiconductor equipment is disclosed. In some embodiments, the method includes: determining a set of signals, from a plurality of sensors of the semiconductor equipment, to monitor during a process to be performed by the semiconductor equipment, the plurality of sensors comprising at least one spatial sensor, at least one spectral sensor, and at least one temporal sensor; based on the process to be performed, performing sensor measurements via two or more of (i) the at least one spatial sensor, (ii) the at least one spectral sensor, or (iii) the at least one temporal sensor; and determining the state of the semiconductor equipment based on the sensor measurements.

In another aspect of the present disclosure, a multi-sensor measurement apparatus is disclosed. In some embodiments, the multi-sensor measurement apparatus includes: a housing having a principal dimension that is about 10 inches or less; a spectral sensor within the housing; a spatial sensor within the housing; a temporal sensor within the housing; and a physical interface shaped to allow the housing to attach to a surface of the fabrication tool and receive, through a window of the fabrication tool, electromagnetic signals related to a process performed by the fabrication tool.

In another aspect of the present disclosure, a method for multi-sensor determination of a process chamber clean endpoint is disclosed.

In another aspect of the present disclosure, a method for determining a presence of unexpected species within a process chamber is disclosed.

These and other features of the disclosed embodiments will be described in detail below with reference to the associated drawings.

### BRIEF DESCRIPTION OF DRAWINGS

FIG. 1A shows a fabrication tool for depositing or etching a film on or over a substrate utilizing a plasma process; the tool includes a camera sensor.

FIG. 1B presents a schematic view of an implementation of a multi-station processing tool; the tool includes four camera sensors.

FIG. 1C presents a top view of an electronic device fabrication system having four multi-station fabrication tools, one of which includes camera sensors.

FIG. 2 schematically depicts a process chamber with an example camera oriented to capture images along a horizontal line of sign into the chamber interior.

FIG. 3 schematically depicts a process chamber with example cameras oriented to capture images along vertical lines of sight into the chamber interior.

FIG. 4 is a schematic view of an example optical emission spectrometry (OES) sensor, according to some embodiments.

FIG. 5 is a flow diagram illustrating a method for determining a state of semiconductor manufacturing equipment, according to some embodiments.

FIGS. 6A and 6B are flow diagrams illustrating methods for determining a state of semiconductor manufacturing equipment, according to some embodiments.

FIGS. 7A and 7B are flow diagrams illustrating methods for determining a state of semiconductor manufacturing equipment, according to some embodiments.

FIG. 8 is a block diagram illustrating a hardware configuration for a multi-sensor fabrication tool (e.g., a multi-station fabrication tool) implementing a combined set of sensors utilizing multiple types of sensors for manufacturing equipment, according to some embodiments.

FIG. 9 illustrates a diagram of a cross-sectional view of an example viewport of a fabrication tool (e.g., multi-sensor fabrication tool of FIG. 8), the viewport having a set of sensors associated therewith, according to some embodiments.

FIG. 10 illustrates a diagram of an external perspective view of a chamber for the example viewport of the fabrication tool, according to some embodiments.

FIG. 11 is a flow diagram illustrating a method for multi-sensor determination of a process chamber clean endpoint, according to some embodiments.

FIGS. 12A and 12B are flow diagrams illustrating methods for determining a presence of unexpected species within a process chamber, according to some embodiments.

FIG. 13 shows a schematic diagram of components of a computing device that is implemented in a computing system in accordance with some implementations.

### DETAILED DESCRIPTION

This disclosure relates to characterization of semiconductor equipment, such as multi-station process chambers, using a multi-sensing system. The current approach for sensing and monitoring the state of semiconductor equipment typically involves employing a sensor for a respective task or class of tasks. The measurements obtained from individual sensors are used in isolation to obtain or infer indications of one or more characteristics relating to the equipment. In some cases, expert judgement is used to determine the characteristics based on experience or intuition or based on results obtained from other sensors or techniques. That is, a human element may be needed with sensing techniques to derive meaningful data in some cases.

In some typical scenarios relating to process engineering, process performance checks are performed by, e.g., visually verifying how plasma behaves a certain way when viewed through a viewport, based on sensor response to one of hundreds of correlated channels, or (most often) through performance on a substrate (e.g., a 300-mm wafer) after process is completed. These approaches do not provide an instantaneous response. Engineers do not always have time to check the plasma for each recipe, and subtle system drifts may not be easily comprehended by visual inspection in fast changing systems, as plasma dynamics are in the order of microseconds (us) to milliseconds (ms). Constant monitoring of correlated channels is not feasible without automated systems, and subtle changes may either not be captured with the current implementations of sensors or may be deemed as noise in the system. The most reliable (and most frequently used) indicator of process change is the impact a certain recipe has after process. Post-process metrology indicates whether a system state has changed, using the response of properties on the wafer (deposited film thickness, refractive index (RI), etc.). However, not all wafers are measured after process. These sensing inefficiencies can result in yield impact or wafer scrap and does not make real-time control feasible.

In some typical scenarios relating to clean endpoint (i.e., endpoint of a chamber clean), endpoint detection relies on either timed cleans (which does not account for system or process variability and/or changing accumulation based on differing processes) or using IR-EPD. IR-EPD looks for a certain voltage and slope of the signal and adds an overetch step. The overetch step may result in significant etching in some regions of the stations, reducing the lifetime of pedestal, e.g., because of aluminum fluoride (AlF₃) formation. Another method of endpoint detection in chamber clean involves using visual signal, e.g., using a camera. Such visual-based detection is limited to visible regions, however, and accurately determining which region cleans the slowest or is the last part requires extensive validation.

Thus, a sensing approach that can acquire and provide consistently accurate signals in an automated manner to provide a better understanding of the state of the equipment system as well as provide control opportunities is desired.

The following terms are used throughout the present specification:

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers. In some embodiments, the manufacturing equipment may be a multi-station process chamber having, e.g., four stations.

As referred to herein, manufacturing equipment is sometimes simply referred to as a “process chamber.” In various embodiments, a process chamber is typically a sealed enclosure in which a substrate is immobilized during processing. The process chamber may include components associated with delivery of and removal of gases. It may also include components associated with generating a plasma and controlling properties of the plasma within the chamber. It may include components for controlling the pressure, including pulling a vacuum within the chamber. In the context of this disclosure, the process chamber may include a pedestal on which the substrate sits while it is being processed. A pedestal may be outfitted with a chuck such as an ESC to hold the substrate in position during processing.

A “semiconductor device fabrication operation” as used herein is an operation performed during fabrication of semiconductor devices. As referred to herein, such a fabrication operation is sometimes simply referred to as a “process” or as “processing.” Examples of processing include deposition of a material on a substrate, selectively etching material from a substrate, and ashing of photoresist on a substrate. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The work piece may be of various shapes, sizes, and materials.

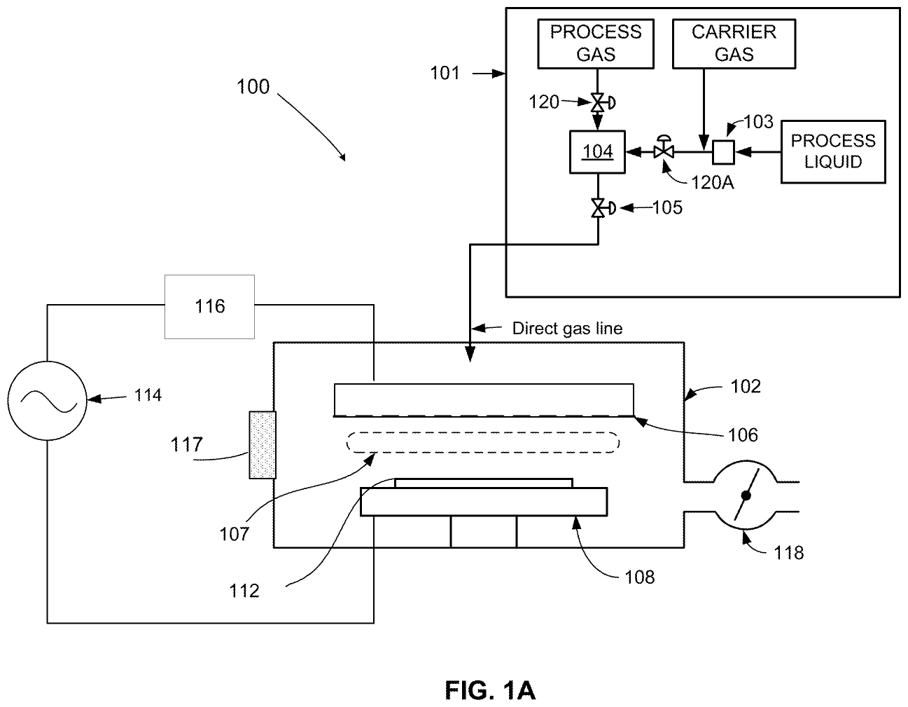

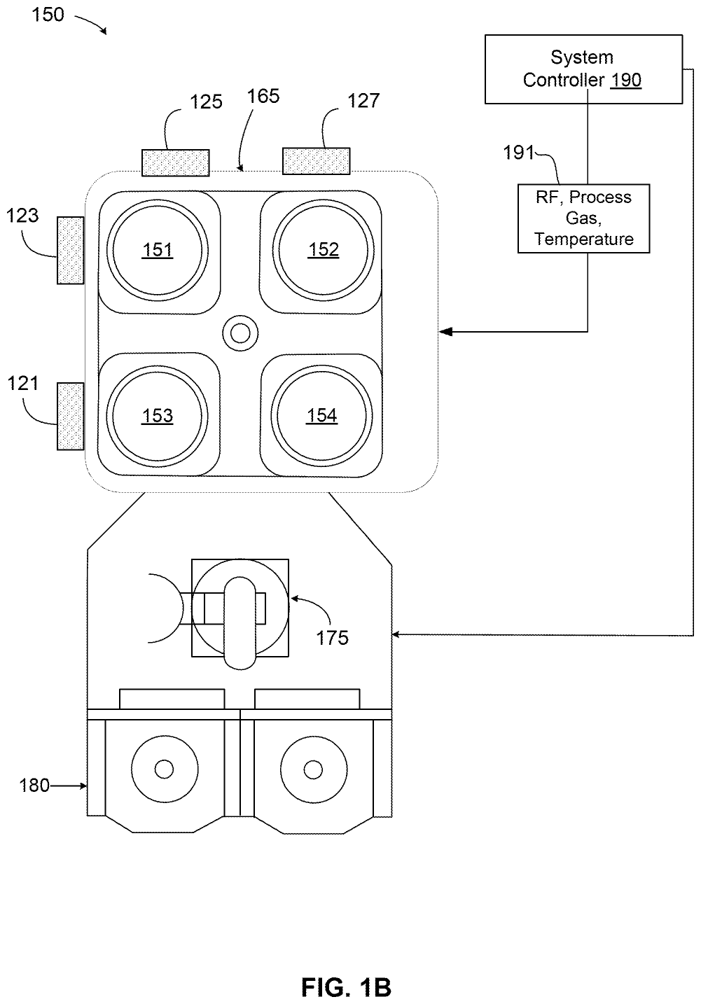

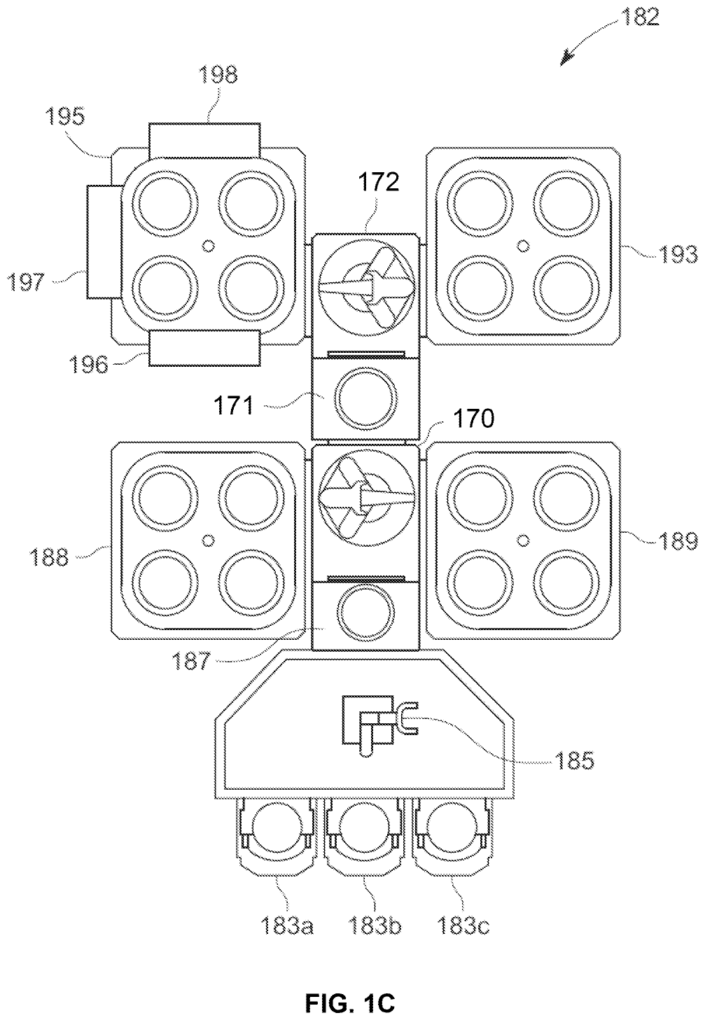

FIG. 1A shows a fabrication tool denoted as substrate processing apparatus 100. In various embodiments, substrate processing apparatus 100 may be configured to deposit films on or over a semiconductor substrate utilizing any number of processes. For example, substrate processing apparatus 100 may be configured to perform plasma-enhanced chemical vapor deposition (PECVD) or plasma-enhanced atomic layer deposition (PEALD). Substrate processing apparatus 100 may include one or more sensors or sensor packages 117 on a chamber wall. When implemented as a sensor package, element 117 may include two or more different sensors, which may be different types of sensors. In certain embodiments, the sensors include two or three of the following sensor types: spatial, spectral, and temporal. Sensor(s) or sensor package(s) 117 may be configured to capture image data from the interior of apparatus 100. Note that while sensor(s) or sensor package(s) 117 is shown as a single block, it represents implementations in which one, two, or more sensors are located proximate to one another, optionally sharing a single viewport or other window. In some cases, the individual sensors within block representing the sensor or sensor package 117 are trained on different components or fields of vision within a chamber interior. In some cases, the individual sensors within block 117 may be configured to capture different respective spectral ranges (far IR, near IR, visible, UV, etc.).

Substrate processing apparatus 100 of FIG. 1A may employ a single process station 102 of a process chamber with a single substrate holder 108 (e.g., a pedestal) in an interior volume, which may be maintained under vacuum by a vacuum pump 118. A showerhead 106 and a gas delivery system 101, which are fluidically coupled to the process chamber, may permit the delivery of film precursors, for example, as well as carrier and/or purge and/or process gases, secondary reactants, etc.

In FIG. 1A, a gas delivery system 101 may include a mixing vessel 104 for blending and/or conditioning process gases for delivery to showerhead 106. One or more mixing vessel inlet valves 120 may control introduction of process gases to mixing vessel 104. Particular reactants may be stored in liquid form prior to vaporization and subsequent delivery to process station 102 of a process chamber. The implementation of FIG. 1A may include a vaporization point 103 for vaporizing liquid reactant to be supplied to mixing vessel 104. In some implementations, vaporization point 103 may include a heated liquid injection module. In some other implementations, vaporization point 103 may include a heated vaporizer. In yet other implementations, vaporization point 103 may be eliminated from the process station. In some implementations, a liquid flow controller upstream of vaporization point 103 may be provided for controlling a mass flow of liquid for vaporization and delivery to process station 102.

Showerhead 106 may operate to distribute process gases and/or reactants (e.g., film precursors) toward a substrate 112 at the process station, the flow of which may be controlled by one or more valves upstream from the showerhead (e.g., valves 120, 120A, 105). In the implementation depicted in FIG. 1A, substrate 112 is depicted as located beneath showerhead 106, and is shown resting on a pedestal 108. Showerhead 106 may include any suitable shape and may include any suitable number and arrangement of ports for distributing process gases to substrate 112. In some implementations involving two or more stations, gas delivery system 101 may include valves or other flow control structures upstream from the showerhead, which can independently control the flow of process gases and/or reactants to each station so as to permit gas flow to one station while prohibiting gas flow to a second station. Furthermore, gas delivery system 101 may be configured to independently control process gases and/or reactants delivered to each station in a multi-station apparatus such that the gas composition provided to different stations is different; e.g., the partial pressure of a gas component may vary between stations at the same time.

In the implementation of FIG. 1A, gas volume 107 is depicted as being located beneath showerhead 106. In some implementations, pedestal 108 may be raised or lowered to expose substrate 112 to gas volume 107 and/or to vary the size of gas volume 107. The separation between pedestal 108 and showerhead 106 is sometimes referred to as a “gap.” Optionally, pedestal 108 may be lowered and/or raised during portions of the deposition process to modulate process pressure, reactant concentration, etc., within gas volume 107. Showerhead 106 and pedestal 108 are depicted as being electrically coupled to an RF signal generator 114 and a matching network 116 for coupling power to a plasma generator. Thus, showerhead 106 may function as an electrode for coupling radio frequency power into process station 102. RF signal generator 114 and matching network 116 may be operated at any suitable RF power level, which may operate to form plasma having a desired composition of radical species, ions, and electrons. In addition, RF signal generator 114 may provide RF power having more than one frequency component, such as a low-frequency component (e.g., less than about 2 MHz) as well as a high frequency component (e.g., greater than about 2 MHz). In some implementations, plasma ignition and maintenance conditions may be controlled with appropriate hardware and/or appropriate machine-readable instructions in a system controller which may provide control instructions via a sequence of input/output control instructions.

In general, the disclosed embodiments may be implemented with any plasma-assisted fabrication tool, including integration of sensors (including, e.g., sensor(s) or sensor package(s) 117) configured to acquire data (including, e.g., images) relating to plasmas and/or plasma-related phenomena. Example deposition apparatus include, but are not limited to, apparatus from the ALTUS® product family, the VECTOR® product family, and/or the SPEED® product family, the KIYO® product family, the STRIKER® product family, and the VERSYS® product family, each available from Lam Research Corp. of Fremont, Calif., or any of a variety of other fabrication tools employing plasma.

In addition, in some embodiments, the sensors or sensor packages as described herein may be capable of serving multiple purposes. As one example, a sensors or sensor package may be or include a hyperspectral sensor (which is configured to capture intensity values in numerous narrow wavelength bins) or a multispectral sensor (which is configured to capture intensity values over broader wavelength bins, typically fewer than the numerous narrower bands of hyperspectral sensing). A hyperspectral or multispectral sensor may thereby provide both spatial and spectral sensor information, where the spectral information may correspond to wavelengths outside of the visible spectrum (e.g., at least a portion of the ultraviolet (UV) spectrum, at least a portion of the infrared (IR) spectrum). As another example, a sensor may possess sufficiently heightened capabilities to provide functions of any two or more types of sensor. For instance, a camera with a very fast frame rate (e.g., 120 frames per second or more) may capture spatial and temporal information and thus serve as both a spatial sensor and a temporal sensor.

Referring now to FIG. 1B, an implementation of a multi-station fabrication tool 150 is depicted, according to some embodiments. For simplicity, processing apparatus 100 is depicted in FIG. 1A as a standalone station 102 of a process chamber for maintaining a low-pressure environment. However, some fabrication tools employ a plurality of process stations such as those shown in FIG. 1B. In some embodiments, multi-station fabrication tool 150 may employ a process chamber 165 that includes multiple fabrication process stations, each of which may be used to perform processing operations on a substrate held in a wafer holder, such as pedestal 108 of FIG. 1A, at a particular process station. In the implementation of FIG. 1B, the process chamber 165 is shown as having four process stations 151, 152, 153 and 154. However, in certain other implementations, multi-station processing apparatuses may have more or fewer process stations depending on the implementation and, for instance, the desired level of parallel wafer processing, size or space constraints, or cost constraints. FIG. 1B additionally shows a substrate handler robot 175, which may operate under the control of a system controller 190. The substrate handler robot 175 may be configured to move a substrate from a wafer cassette (not shown in FIG. 1B) from a loading port 180 and into the multi-station process chamber 165 and onto one of process stations 151, 152, 153 or 154.

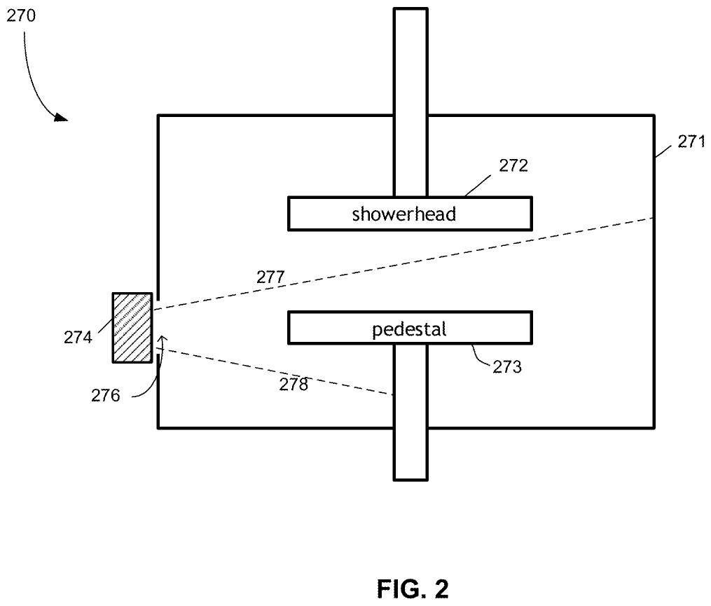

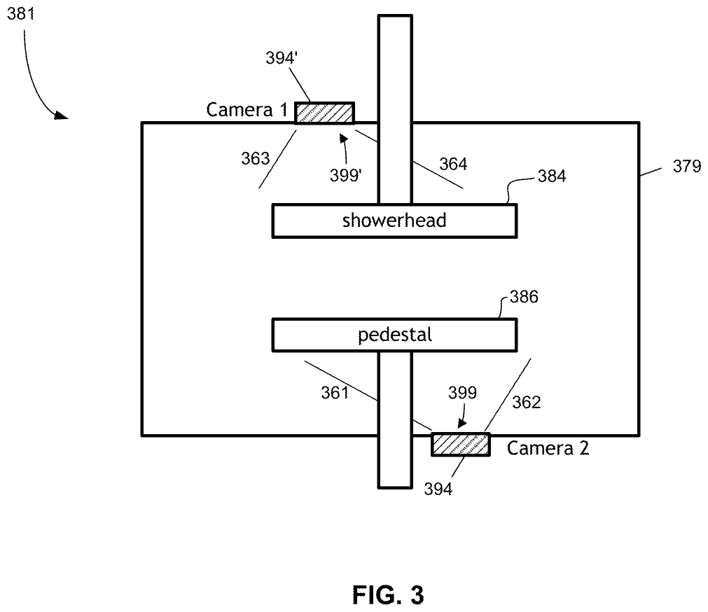

As depicted in FIG. 1B, process station 153 has an associated sensor or sensor package 121 located and configured to obtain in situ information (e.g., image, spectral, and/or temporal data) from within process station 153 and, in some embodiments, from within process chamber 154. Process station 151 may have two associated sensors or sensor packages 123 and 125. Sensor or sensor package 123 is located and configured to obtain in situ information from within process station 151 and, in some embodiments, from within process chamber 152. Sensor or sensor package 125 is located and configured to obtain in situ information from within process station 151 and, in some embodiments, from within process chamber 153. Process station 152 may have an associated sensor or sensor package 127 located and configured to obtain in situ information from within process station 152 and, in some embodiments, from within process chamber 154. When implemented as a sensor package, elements 121, 123, 125, 127 may include two or more different sensors, which may be different types of sensors. Any one or more of sensors or sensor packages 121, 123, 125 or 127 may be coupled to the interior of process chamber 165 via a viewport or other window disposed in the chamber wall. Additionally, while not shown in FIG. 1B, some embodiments may include one or more sensors or sensor package adjacent to the process station 154. Example positioning of sensors or sensor packages will be described further with respect to FIGS. 2 and 3 below. Moreover, as will be described in detail below, each sensor or sensor package may be a combination of at least a spatial sensor, at least a spectral sensor, or at least a temporal sensor, e.g., two or more of these types of sensors. Some sensors may be a standalone sensor of one type, but the present disclosure describes use applications for sensors incorporating multiple types for greater accuracy, precision, stability, and completeness of measurements.

In the context of the present disclosure, the terms precision, stability, and matching may refer to the sigma (σ, standard deviation) of a process metric (measurement result) reported by the sensor or sensor package in high volume manufacturing (HVM). Ostensibly, the same process is measured repeatedly and over extended periods of time with multiple copies of the sensor or sensor package (the measurement equipment). The same sensor package may be installed at multiple stations within a process module, and at multiple process modules, with process modules installed on multiple tools possibly at multiple HVM lines in different locations. These in-line HVM process metrics from the sensor or sensor package can be used to develop correlations with other HVM process metrics including those acquired using precision off-line specialized metrology techniques. Such correlations may then enable near real-time process optimization and root-cause analysis of process deviations.

Measurement results or metrics may be recorded by a host device (e.g., computing device) receiving the data. Precision may be defined as the sigma of a metric repeated over the shortest possible time under nearly identical conditions. Precision may quantify or represent the fundamental limit of a metric, and generally requires more than 10 input values of the metric to be used to calculate the sigma where the values are acquired in rapid sequence, without unnecessary interruption. Stability may be defined as the sigma of a metric reported over a defined time period. Stability may quantify or represent a process study or a gage study (indicating repeatability and reproducibility of measurements), which typically occurs over multiple days, such as over the lifetime of a process kit. Process stability and gage stability may not be easily separable in the data for many metrics. Prudent use of stability results across multiple metrics can help identify gage drift from process drift. High stability is beneficial because predictive maintenance and process throughput improvements must be based on metrics with known stability. Matching may be defined as the sigma of a metric over multiple sensors or sensor packages acquired over multiple days (stability data sets of sensor sub-systems). One example of matching is within a single process module (PM) containing multiple sensor sub-systems. In particular, in intra-PM matching, multiple sub-systems on a single PM can be used to quantify the metric's PM matching sigma. With inter-PM matching, matching may be measured, e.g., within a fabrication tool, across fabrication tools, or across installed base at multiple sites. Sub-system (e.g., of a sensor or sensor package) specific control limits can be used to manage matching nonidealities, but this approach is cumbersome. Metrics that well match across well-functioning sub-systems are preferred. Generally, process precision is easiest (single chamber, short time), process stability is harder to achieve (because of, e.g., drift over time), and chamber-to-chamber or tool-to-tool process variation is the hardest.

In some implementations, the sensor or sensor package may report metrics to the host device as a function of time. This data can be further refined to define customized metrics by the end user of the sensor or sensor package. The precision, stability and matching of metrics help define the limits of the sensor package to manage the underlying process. In the end, process precision, process stability and process matching are desirable for the sensor or sensor package, e.g., using it to develop process metrology techniques, perform process quality control (e.g., establishing whether a behavior is normal, whether abnormal behavior is an impulse or a drift issue, whether a behavior warrants corrective action), and establish process tolerance limits for metrics end users find to be important.

In some embodiments, fabrication tool 150 may include the system controller 190 configured to control process conditions and hardware states of the fabrication tool 150. In some embodiments, the system controller 190 may interact with one or more sensors, gas flow subsystems, temperature subsystems, and/or plasma subsystems—collectively represented as a block representing subsystems 191—to control process gas flow, thermal conditions, and/or plasma conditions as appropriate for controlling a fabrication process. In various implementations, the system controller 190 and the subsystems 191 may act to implement a recipe or other process conditions in one or more of the process stations (e.g., 151-154) of the process chamber 165. A system controller may be fully located on or in close proximity to a fabrication tool (e.g., as an edge computer in manufacturing equipment), or a system controller may be fully located remote from the fabrication tool (e.g., on a hosted cloud computing resource), or a system controller may be partially located on manufacturing equipment and partially located remotely.

In multi-station fabrication tools, an RF signal generator may be coupled to an RF signal distribution unit, which is configured to divide the power of the input signal into, for example, four output signals. Output signals from an RF signal distribution unit may possess similar levels of RF voltage and RF current, which may be conveyed to individual process stations (e.g., 151-154) of a multi-station fabrication tool.

FIG. 1C provides a top view of an electronic device fabrication system 182 having four quad-station fabrication tools 188, 189, 193 and 195. Quad-station fabrication tools 188, 189, 193 and 195 may be examples of stations 151-154 of FIG. 1B. Each quad-station tool contains four process stations, each configured to hold and process a substrate. At the front end of the electronic device fabrication system 182 are three front opening unified pods (FOUPs) 183a, 183b and 183c accessible by a front-end wafer handling robot 185, which is configured to transfer wafers between the FOUPs and a first load lock 187. A first wafer handler 170 may be located and configured to transfer wafers between the first load lock 187 and quad-station fabrication tools 188 and 189. The first wafer handler 170 may also configured be to transfer wafers to a second load lock 171 which makes wafer available to quad-station fabrication tools 193 and 195 via a second wafer handler 172.

In some embodiments, the quad-station tool 195 (as an example) may include three sensors or sensor packages 196, 197 and 198 disposed around its outer wall. In FIG. 1C, the sensors or sensor package 196-198 are shown vertically affixed to three sides of the four-sided chamber of tool 195. In the embodiment shown, the only side without a sensor or sensor package is the side next to the wafer handler 172. While not shown in FIG. 1C, similar sensor or sensor package arrangements can be provided on any one or more of each of the three other quad station chambers 188, 189 or 193 in the system. Further, in some implementations, a sensor or sensor package may still be placed on the side next to the wafer handler 172. FIGS. 2 and 3 illustrate different possible sensor or sensor package positions. Myriad other positioning of one or more sensors (including combinations of sensors together or separately in a sensor package) are possible depending on, e.g., the measurements, angles, locations to measure desired. It should be understood that, in some cases, a system controller (e.g., 190 of FIG. 1B) may be configured to modify a position or orientation of a given sensor or sensor package (e.g., up, down, left, right, diagonal, azimuthal, elevational).

FIGS. 2 and 3 schematically illustrate fabrication tools with sensors or sensor packages oriented to capture information (e.g., spatial, spectral, and/or temporal) from a horizontally directed and a vertically directed line of sight, respectively. In some embodiments, each sensor or sensor package described may include two or more types of spatial, spectral, or temporal sensors of the type described below, combined in such a way that each of the types can obtain information and measurements serially (e.g., based on a trigger condition being met or not met by one sensor type) or in parallel (e.g., two or more sensor types collecting information concurrently).

FIG. 2 shows a process chamber 270 having a chamber wall 271, a showerhead 272, and a pedestal 273, which may be designed and constructed in any manner that is known in the art, FIG. 2 merely serving to illustrate an example position and angle of view of an example sensor or sensor package 274. FIG. 2 also shows the example sensor or sensor package 274 arranged to capture in situ information from the interior of process chamber 270 via a viewport or window 276 designed for sensor or sensor package access (e.g., a sapphire rod having a diameter of 1-10 mm). Sensor or sensor package 274 may have a field of view defined by edges 277 and 278. As illustrated sensor or sensor package 274 and window 276 are arranged to allow the sensor 274 to, e.g., capture plasma images, spectral information relating thereto, and/or temporal information relating thereof, including the vertical edge of the pedestal 273. Other arrangements may permit the sensor or sensor package to capture thermal images of other vertical edges in the process chamber 271, as well as other information such as pressure, temperature, voltage, current, or other measurements of the process chamber or a particular station depending on whether sensors capable of capturing such information are incorporated into sensor or sensor package 274.

FIG. 3 shows a similar process chamber 381 but with example sensors or sensor packages 394 and 394′ having a vertical line of sight to allow capture of information of other features within the process chamber 381. In specific embodiments, the process chamber 381 may have a chamber wall 379, a showerhead 384, and a pedestal 386, all designed and constructed in any manner that is known in the art, FIG. 3 merely serving to illustrate an example position and angle of view of example sensors or sensor packages 394 and 394′. FIG. 3 shows vertically oriented sensors or sensor packages 394 and 394′ arranged to capture in situ information from the interior of process chamber 381 via viewports or windows 399 and 399′ designed for sensor or sensor package access. Sensor or sensor package 394 may have a field of view defined by edges 361 and 362, while sensor or sensor package 394′ may have a field of view defined by edges 363 and 364. As illustrated, sensor or sensor package 394 and window 399 may be arranged to allow the sensor or sensor package 394 to capture plasma images including a stem or lower side of pedestal 386. As illustrated, sensor or sensor package 394′ and window 399′ may be arranged to allow the sensor or sensor package to capture, e.g., capture plasma images, spectral information relating thereto, and/or temporal information relating thereof, including an edge of a stem and/or backside of showerhead 384. Other arrangements may permit the sensor or sensor package to capture thermal images of other edges in the process chamber 381, as well as other information such as pressure, temperature, voltage, current, or other measurements of the process chamber or a particular station depending on whether sensors capable of capturing such information are incorporated into sensors or sensor packages 394 and 394′.

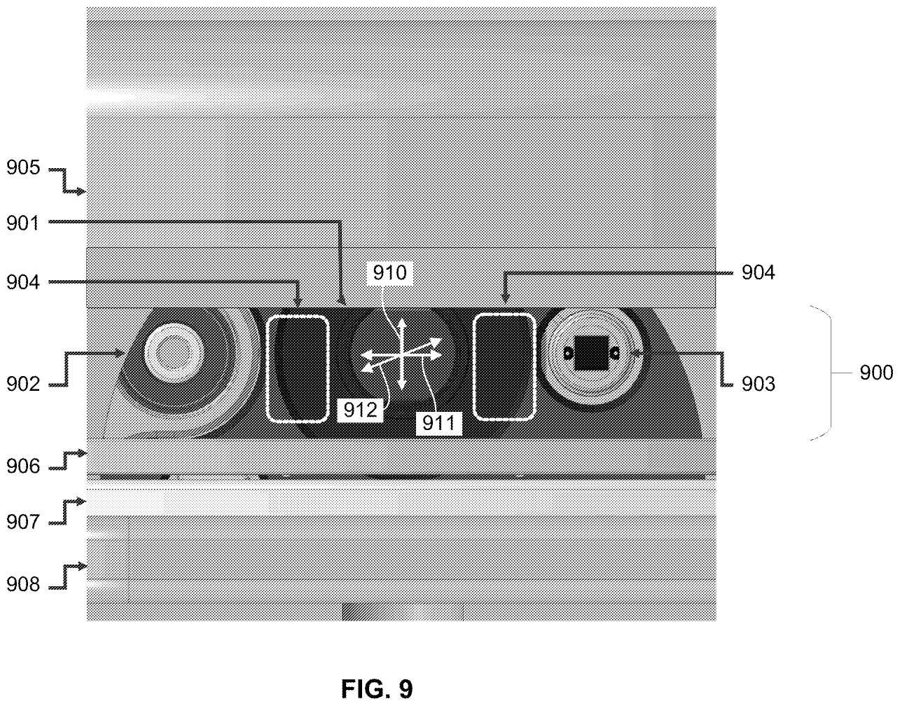

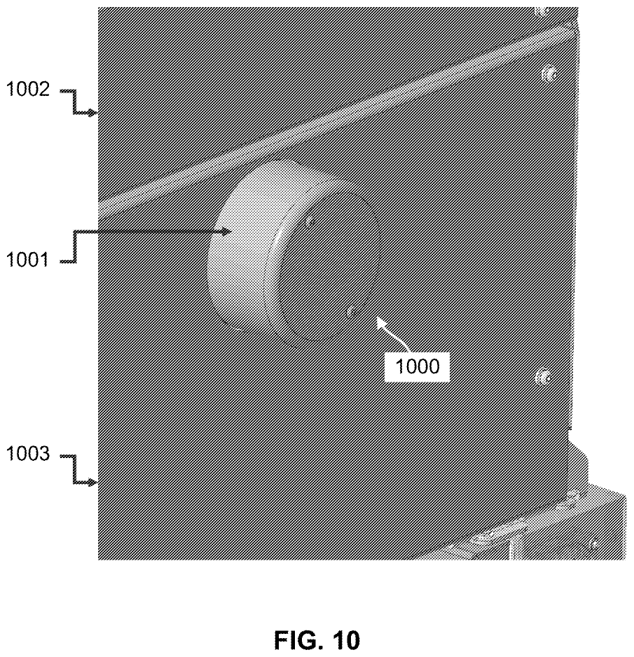

A sensor or sensor package can be disposed outside of a fabrication tool, although in some embodiments, it can be integrated with a chamber wall or other component or assembly within the chamber, as is shown in FIGS. 9 and 10. In certain embodiments, a viewport or window specially constructed for a sensor may be integrated into a chamber wall. In certain embodiments, a sensor or sensor package may be coupled to an interior of a fabrication tool using an access aperture that is provided in or on a chamber wall to allow visual inspection of the tool interior.

### Sensors and Sensor Configurations

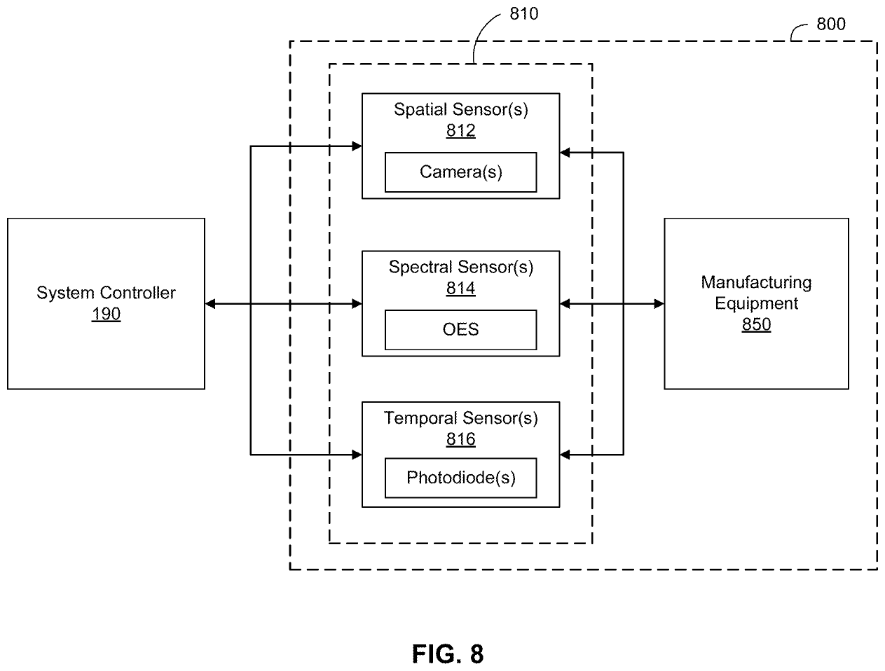

In various embodiments of the present disclosure, multiple sensors such as two or more of at least one spatial sensor (e.g., camera), at least one spectral sensor (e.g., optical emission spectrometry (OES) sensor), and/or at least one temporal sensor (e.g., photodiode) are implemented in one integrated sensor “package” or sensor system, which can be used for varying use applications and tasks in semiconductor systems such as fabrication tools that may include one or more process chambers and/or stations (e.g., multi-station fabrication tool 150, fabrication system 182). Such sensors may be positioned or otherwise configured to sense a plasma or monitor conditions in situ (without removing a wafer from the processing chamber to a separate metrology chamber after the processing to sense or monitor) and in real time (i.e., while the process is being performed on the wafer and on a time scale comparable to that of events occurring in the process chamber). To these ends, sensors may be integrated with a viewport or other window providing visual access to within a process chamber, as will be described with respect to FIG. 8 below.

In disclosed embodiments, such a sensor package may allow monitoring equipment or personnel to solve several problems currently faced in a given semiconductor equipment by providing two or more of spatial, spectral, or temporal information from respective types of sensors. Such spatial, spectral, and/or temporal information, when analyzed in conjunction (e.g., using combined likelihoods, a machine learning model, or other algorithm), can provide a better understanding of the state of a system associated with the semiconductor equipment. The information may also provide control opportunities resulting in benefits including cost savings, improved machine availability (MA, how much unit time a machine is available for processing, e.g., a wafer), improved green-to-green (GtG) periods (reduced downtime periods) and throughput, and improved wafer-to-wafer (WtW) uniformity and wafer quality, as well as greater precision, stability, and matching from combined utilization of different types of sensors that are conventionally used independently. In various use cases, different sensors may play a role as a primary indicator, a secondary indicator, and/or a tertiary indicator. In some implementations, optionally, and additional to the spatial, spectral, and/or temporal sensors, other sensors in the monitoring system may acquire readings including voltage and current (VI), pressure, temperature, etc.

### Spatial Sensors

In various embodiments, a spatial sensor may be an image capture device (e.g., a camera or camera sensor) configured to acquire visual or optical information (e.g., image data, time-of-flight (TOF) data, or both) such that an image of radiation intensity in at least two dimensions can be provided (e.g., 2D area array of image data having x by y pixels). The spatial sensor may be able to provide images of in-chamber features such as plasma characteristics. Plasma characteristics may include plasma boundaries, plasma location, whether the plasma is anomalous or parasitic. The spatial sensor may also be able to provide images of chamber component boundaries and gas flow patterns (e.g., over time or at a given instant).

Camera sensors, which are examples of spatial sensor, may be characterized by various parameters including the number of pixels, range of wavelengths captured, and the like. In some embodiments, a camera sensor for capturing information about a plasma may be capable of multispectral or hyperspectral imaging and sensing intensity values across the electromagnetic spectrum, including visible radiation at wavelengths including at least a portion of the visible spectrum. As an example, a camera sensor may be configured to sense intensity values over one or more ranges, e.g., including 100 nm to 1000 nm. In some embodiments, the camera sensor may discriminate among signals from wavelengths in at least portions of the visible spectrum, at least portion of the UV spectrum, at least a portion of the IR spectrum, or any combination thereof. As an example, a camera sensor that captures both IR and visible information may provide information relevant to thermal processes as well as plasma processes.

As examples for any embodiments herein, camera sensors may be constructed as charge-coupled devices (CCDs) or complementary metal oxide semiconductor (CMOS) arrays. In some implementations, Quanta Image Sensors (QIS) and Single-Photon Avalanche Diode (SPAD) array detectors for imaging and time-of-flight may be included as varieties within CMOS arrays. In certain embodiments, a camera sensor as used herein may have at least about 5 megapixels or at least about 12 megapixels. In some embodiments, a camera sensor used herein may have as few as about 2 megapixels. A multispectral sensor may use a color filter array (CFA) tiled over the entire detector array. Another type of array tiled over the entire detector array of a camera may be a polarizer filter array (PFA). Polarized images can enable spatially resolved thin film stress detection among other applications.

In some implementations, the image capture device is a line or one-dimensional array of sensors or pixels. Such device may be configured to scan across a two-dimensional field of view. The scan direction may be substantially perpendicular to the axis of the line of sensors. In some embodiments, a one-dimensional image capture device is oriented perpendicular to the wafer or chamber component and optionally configured to scan from one side of the chamber to the other (or within other portion or field of view within the chamber). In some implementation, the image capture device includes an array of detectors in multiple dimensions (e.g., a two-dimensional array of detectors). The image capture device may be configured to access a multi-dimensional field of view within a process chamber.

In certain embodiments, a camera as used in any of the embodiments herein may be configured with a shutter. In some embodiments, a camera may be configured to capture video data of a plasma in a fabrication tool. In certain embodiments, a camera may be configured to capture video information of a plasma in a fabrication tool at a frame rate of about 30-120 frames per second, or about every 1-100 ms. In some embodiments, the camera need not provide a fast capture rate (e.g., more often than about every 1 ms or more) and may have a capture rate below that of a standard video, e.g., below about 30 frames per second, below about 10 frames per second, or below about 1 frame per second. In some implementations, the shutter may be employed to capture a frame manually.

Some fabrication tools include a still image or video display. Such display may be employed to allow process engineers or other staff to view the too interior when a camera sensor or light conduit blocks access to a view port from outside the tool. In some embodiments, a view to a chamber interior is provided via images or video streamed electronically (e.g., using the real-time streaming protocol (RTSP), the real-time messaging protocol (RTMP), low-latency HTTP live streaming (HLS), secure reliable transport (SRT), WebRTC, or the like), optionally to a remote location via a web application. Examples of remote sites include a fab monitoring room or facility, a smart phone, a tablet, and/or a desktop computer system. In some embodiments, communication of the image(s) or video is made via network that includes, as a node, a camera on a process chamber. Such network may be wired or wireless, e.g., a mesh network. In certain embodiments, a network may employ a communication protocol employing Wi-Fi, Bluetooth, cellular, etc.

In some embodiments, image analysis logic may be configured to receive sensed values from one or more camera sensors on a fabrication tool. In certain embodiments, inputs to the image analysis logic include pixel-by-pixel intensity values as a function an observable parameter such as wavelength, time, polarization, or any combination thereof. In certain embodiments, input data from a camera sensor is provided in the form of image data, video data, spectral values, time series data, wafer metrology data and the like. In some embodiments, the input data is filtered by wavelength, polarization, etc. In some embodiments, analysis logic is configured to receive and act on additional input information beyond camera sensor intensity data. Such additional input information may include metadata about the camera sensor and/or associated camera components, substrate metrology information, historical information about the fabrication tool, etc.

The analysis logic may be configured to output one or more properties of plasma in a fabrication tool and/or a classification of a state of the fabrication tool or a component thereof. In some cases, analysis logic may be configured to perform an image processing routine such as a segmentation or other edge finding routine. In certain embodiments, analysis logic may be configured to use segmentation or other edge detection method to determine plasma property information relative to a system component.

Moreover, in some embodiments, camera sensor analysis logic may include any of various types of classifiers or models such as deep neural networks (e.g., convolutional neural networks, autoencoders, U-Net), traditional or classical computer vision methods such as edge detection, image modification (such as blurring, changing contrast), intensity thresholding, color channel thresholding, etc.

The logic may employ any of various techniques for edge detection or segmentation. For example, the logic may employ a threshold-based method, a deep learning model, etc. In some embodiments, the edge of a plasma or the boundary of a subregion within a plasma having defined plasma characteristic may be determined.

### Spectral Sensors

A spectral sensor provides wavelength-specific radiation intensity detection. It outputs values of radiation intensity as a function of wavelength or spectral region. A spectral sensor has various capabilities. The information it provides may discriminate among, or identify, particular chemical species; each chemical species has its own particular spectrum. In some implementations, a spectral sensor can discriminate among signal from wavelengths in one or more regions of the electromagnetic spectrum including UV, visible, and IR.

A spectral sensor may be implemented in various ways. Examples of wavelength separation components include (a) dispersive devices (these separate wavelengths in a dispersive medium such as a prism), (b) diffractive device (these separate wavelengths by diffraction using, e.g., a diffraction grating), (c) filters disposed in front of intensity detector so that the detector receives only certain wavelengths of interest.

One example of a spectral sensor detector is a linear array of optical detectors configured to detect wavelength-specific intensities at different detectors in the linear array. An optical detector may be configured to provide an output of intensity as a function of wavelength. A wavelength separation component disposed in front of a linear array provides wavelength separation in one dimension (along the linear array), so that each element of the linear detector is associated with a particular wavelength or a range of wavelengths.

Unlike a spatial sensor, a spectral sensor need not provide multi-dimensional images. Additionally, for some applications the speed at which a spectral sensor acquires data need not be fast (e.g., ≥1 ms capture rate or about 1 ms-1 s).

In certain embodiments, an optical detector for an OES sensor is a linear, one-dimensional array or a two-dimensional array of detector devices. As an example, an OES sensor is a two-dimensional charge couple device (2-D CCD) array where spectrally separated light components are detected by different regions of the 2-D CCD. In some implementations, a linear array of detectors that separately detect wavelength-specific intensities at different detectors in the linear array may be used. Refraction (e.g., a prism) or diffraction (e.g., a grating) may be employed for wavelength separation in one dimension along the linear array. Each element of the linear detector may be associated with a particular wavelength or a range of wavelengths. Various implementations may be employed for different use cases. In some embodiments, an OES sensor for capturing spectral information about a plasma may be capable of sensing intensity values of electromagnetic radiation of, and/or discriminating among signals from, wavelengths including at least portions of the visible spectrum, at least portion of the ultraviolet (UV) spectrum, at least a portion of the infrared (IR) spectrum, or any combination thereof. In some cases, the optical detector does not need to provide a fast capture rate (e.g., more often than about every 1 ms or more). The optical detector may operate at a frame rate of, e.g., about every 1 ms to 1 second.

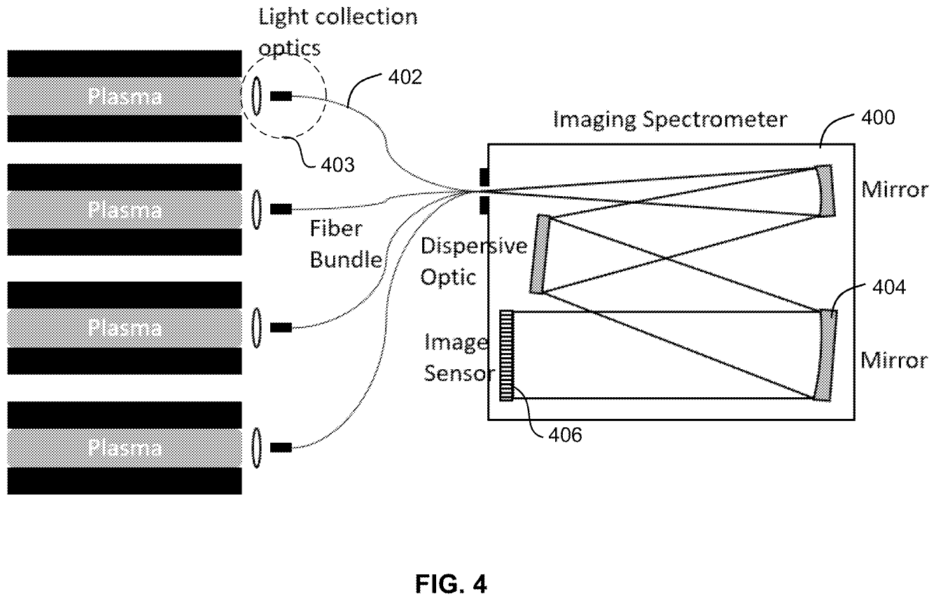

FIG. 4 is a diagram of an example OES sensor 400, according to some embodiments. The OES sensor 400 may be coupled to one or more transmission optical fibers 402. A transmission optical fiber 402 may collect spectral information from a corresponding process, e.g., at a process chamber or a station within a process chamber. For example, a transmission optical fiber 402 may receive spectral information via light collection optics 403 during a process from a process station of a multi-station process chamber (e.g., of the type described with respect to FIGS. 1B and 1C). In some embodiments, each of the four optical fibers 402 is associated with its own process station and collects optical signals emitted from its process station. The transmission optical fibers 402 may be grouped into a bundle and received by the OES sensor 400. As shown in FIG. 4, the OES sensor 400 may receive spatial information from four stations of a four-station process chamber via four transmission optical fibers 402, as one example implementation.

The OES sensor 400 may further include dispersive optics such as one or more mirrors 404, some or all of which may have optical dispersion properties from being coated with varying depths so that different wavelengths have different penetration lengths, allowing a mirror to reflect varying wavelengths of light. The OES sensor 400 may include an image sensor 406 that detects the spatial information, which may include spectrally separated light components.

Myriad other implementations of the OES sensor are possible, including, for example, mounting the OES sensor directly at the viewport, eliminating at least some of the transmission optical fibers 402, eliminating some or all of the light collection optics 403, switching between different optical inputs (e.g., fiber switch, microelectromechanical systems (MEMS) mirror), using a different type of dispersive optics configuration (e.g., gratings, prisms, computed tomography (CT), echelle grating), using a spectral filter (e.g., filter wheel, or in some cases etalon or tunable liquid crystal), using time-domain spectral analysis (e.g., in some cases, using an optical spectrum analyzer).

In some embodiments, a spectral reflectometer device may be used as a spectral sensor. A reflectometer device may include a light source that is used to illuminate the surface in question, and an optical detector. The optical detector may include one or more photodetectors. A fiber optic cable may be connected to the spectral reflectometer device. The optical cable may include transmission optical fibers and receiving optical fibers, where each receiving optical fiber may be connected to a respective individual photodetector. In some cases, a plurality of receiving optical fibers may be connected to a same photodetector.

In some embodiments, phase-sensitive spectroscopic ellipsometry may be used. In some embodiments, reflectometry with polarization control may be used especially with structures that are highly polarizing.

Note that while spatial information may be based on intensity collected by each pixel of the sensor (e.g., camera), spectral sensor intensity counts can be collected for a larger area.

### Temporal Sensors

Temporal sensors may detect and measure temporal characteristics of pulsed light or other bursts of light (e.g., arcs formed in plasma systems). In environments such as a process chamber, temporal sensors may be used to very quickly identify process changes that occur because of its rapid response time (e.g., within about 100 ms, or picoseconds (ps) to microseconds (μs), e.g., 10 ps to 100 ms). By measuring temporal characteristics (e.g., time variation of optical emission as an electrical signal), temporal sensors may measure and/or provide signal data for such process changes. Examples of temporal sensors include photodiode optical sensors, micro-photodiodes, phototransistors, photocells, pulse characterization sensors, photomultiplier tubes, solid-state photomultipliers, or other fast, one-dimension radiation (typically but not necessarily limited to visible light) sensors suitable for use with process chambers or multi-station fabrication tools (e.g., 150, 182) of the type described above. A temporal sensor may be configured to acquire a single point of data in the spatial domain. In some implementations, optical filters or lenses may be used in conjunction with a temporal sensor.

In embodiments using a photodiode or an array thereof, for example, a photodiode may include at least one semiconductor junction (p-n, n-p, p-n-p, n-p-n, p-p-n, etc.), where light falling on the junction may cause formation of electron-hole pairs. As is known to those having ordinary skill in the relevant arts, the electron-hole pairs may migrate to different portions of the junction, producing a voltage and/or a current (if connected to a circuit). In this way, even substantially instantaneous light or bursts of light or photons may be detected (e.g., on a scale of the aforementioned ns to us range). Moreover, there is no need to provide wavelength discrimination or acquire multi-dimensional images.

Variations to the architecture of the photodiode or temporal sensors, such as increase in width of the depletion region of the photodiode, shape of the mesa of the photodiode, number and depth of n or p layers utilized, dopants utilized, junctions utilized, or the amount of bias applied across the junction, may result in modifications to the detectability of the process changes, or indications of process changes (e.g., a light-emitting diode that activates based on a process change that does not emit light or if visible light falls below a certain level), as needed or desired by a particular application (which in the present disclosure describing a combined set of sensors may be one or more of many, as will be discussed further below), e.g., via changes to quantum yield (ratio of photons emitted to photons absorbed) or sensitivity (ratio of current flow to light irradiance) or other metrics. The range of radiation detected may vary depending on the materials used as is known by those of ordinary skill in the relevant arts; one example of wavelengths detected may include 300-1200 nm. In some variants, the photodiode may be a PN photodiode (with P-type and N-type layers), PIN photodiode (with an intrinsic “I-region”), a Schottky photodiode, or an avalanche photodiode. An array of the foregoing may also be used.

In some embodiments, a given process chamber, multi-station fabrication tool, or process chamber thereof may include one or more spatial sensors, one or more spectral sensors, one or more temporal sensors, or a combination thereof. A sensor may be disposed internally or externally to a chamber. A sensor may be attached to an internal or external surface or platform or other component of a chamber, and configured for signal or data communication, e.g., with a controller 190 or subsystem(s) 191.

In some embodiments, one or more additional or alternative sensors may be used, such as those configured to detect or measure other parameters within or associated with a process chamber, e.g., VI, pressure, or temperature.

### Illumination Sources

In some cases, a fabrication tool may include a lighting system or one or more illumination sources configured to illuminate all or one or more portions of an interior of the fabrication tool. In some implementations, a lighting system may be configured to allow a camera to take an illuminated image when the plasma is off (e.g., outside operation or in between pulses). Note that in some cases no lighting system is employed and lighting is used from the plasma itself. In some implementations, a lighting system employs one or more light-emitting diodes (LEDs) or other light sources. The light sources may be monochromatic, polychromatic with discrete emission wavelengths, or broad spectrum. The light source may be active continuously, pulsed synchronously with an operation of a spatial sensor (e.g., one or more camera shutters), pulsed asynchronously with an operation of the spatial sensor (e.g., one or more camera shutters), or pulsed synchronously with other process parameters such as RF generators or gas delivery valves. In some cases, pulsing of the light source can facilitation of detail extraction and provision about an ongoing process inside the fabrication tool. For instance, light can be pulsed synchronously with optical sensing of (e.g., camera shutters closing and/or opening to capture image data, e.g., optical images or video of visible effects and events, e.g., plasma behavior and properties), while spectral sensing does not occur during the pulsed illumination periods so as to not corrupt spectral signals captured between optical imaging. However, pulsing of the light source that is asynchronous with the optical sensing (e.g., operation of camera shutter) can allow other visible information to be captured, such as locations of plasma arcs that can be better detected and localized in the dark as opposed to while a chamber is illuminated. In some implementations, a temporal sensor could additionally or alternatively be used to detect the occurrence and presence of arcing while the chamber is not illuminated by the pulses. It would be beneficial to detect arcs or other artifacts or anomalies that could be damaging to components, which may be more difficult to identify or localize when a chamber is illuminated by pulses. These example illumination pulsing schemes enhance the efficiency and amount of information extracted from the ongoing process, especially useful for short-lived (e.g., on the ms or ps scale as noted above) events and process changes occurring within the fabrication tool. In other implementations, multiple light sources are employed in different locations within or outside the chamber. These multiple light sources can be energized continuously or sequentially with timing managed to enable structured lighting to be utilized to construct super-resolution images of features within the chamber. In some implementations, one or more notch or bandpass filters are provided in front of a light source to produce effects that can support analysis (e.g., identification of particular chemical species by their emission spectra). In some implementations, strobe lighting and other consistent structured lighting may be employed (e.g., using periodic bursts of illumination at, e.g., 10, 30, 60 Hz) to provide additional discrete visual information at a consistent frequency.

An additional use for an illumination source includes illumination of interior components of a process chamber that would otherwise be dark. This allows a spatial sensor to image such components. The images of these components can provide a frame of reference for locating other features within a chamber such as the location of a plasma with respect to a gap between a pedestal and a showerhead or with respect to a chamber wall. It can also permit images of adjacent stations in a multi-station chamber. The location of adjacent stations also can provide a frame of reference for key features to be imaged in a station of interest.

Illumination sources may also be used as a “health check,” e.g., to validate or confirm that systems and sub-systems such as spatial, spectral, and temporal sensors are functioning or operating normally and correctly, to track system drift over time, and to determine if a sensor or illumination source is the source of system decay. Illumination sources can be used as a calibration mechanism for the sensors as well. For example, strobe lighting of particular wavelength(s) may support calibration of spectral OES sensors. In some cases, OES calibration for specific wavelength of lights can be done via software to correct for any shifts. In some approaches, illumination sources may also be used to determine the sensitivity of an optical detector (e.g., photodetector) and adjust any threshold offsets to minimize false positives if the photodiode itself is shifting over time.

### Methods

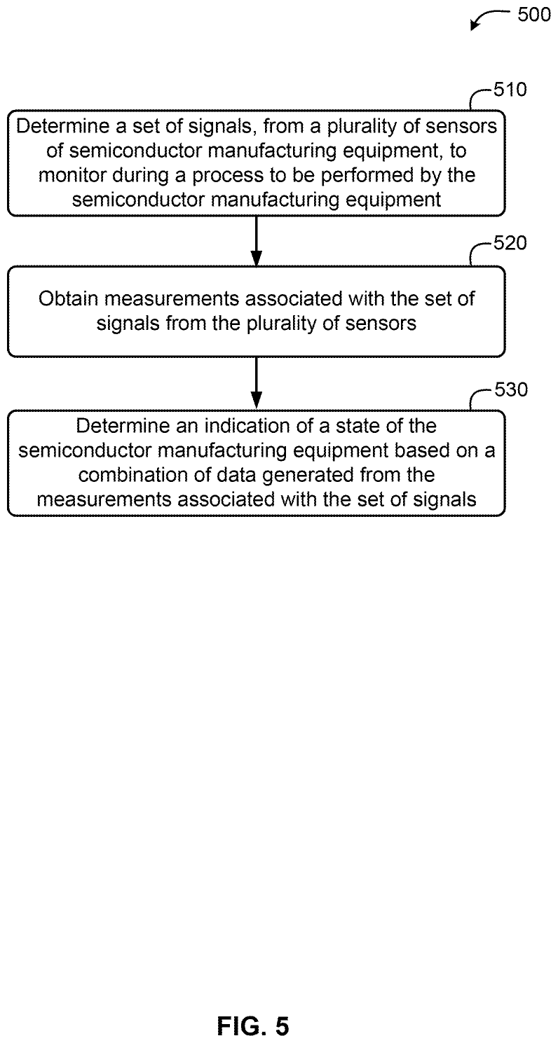

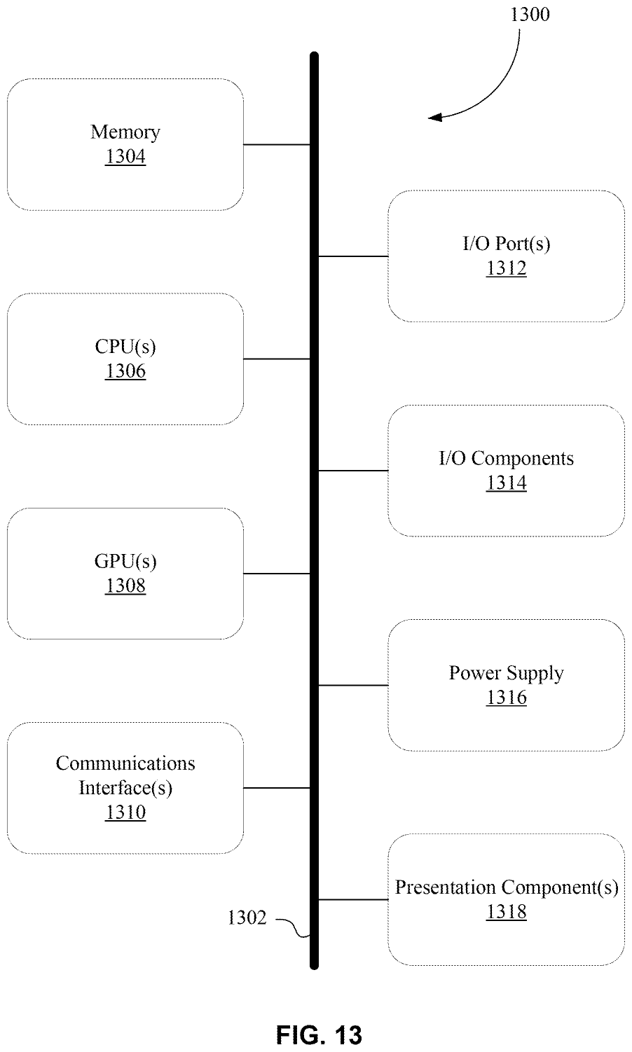

FIG. 5 is a flow diagram illustrating a method 500 for determining a state of semiconductor manufacturing equipment, according to some embodiments. One or more of the functions of the method 500 may be performed by or caused by a computerized apparatus or system. Structure for performing the functionality illustrated in one or more of the steps shown in FIG. 5 may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system. A subsystem (e.g., 191) may be one example of the computerized apparatus or system. A process chamber may be another example of the computerized apparatus or system. Example components of a process chamber and a controller are illustrated in FIGS. 1A and 1B, and 13, respectively, and described in more detail elsewhere herein.

It should also be noted that the operations of the method 500 may be performed in any suitable order, not necessarily the order depicted in FIG. 5. Further, the method 500 may include additional or fewer operations than those depicted in FIG. 5 to determine the state of the semiconductor manufacturing equipment.

As noted above, opportunities for control of a fabrication tool arise when implementing the present disclosure, e.g., using method 500. Management of process parameters and control of the fabrication tool may be approached in three phases: (1) detection, (2) awareness, and (3) control (e.g., change the setpoint, the desired or target value). A consolidated set of sensors such as the multi-sensor system described with respect to FIGS. 8-10 may implement method 500, which may augment, render obvious, or replace conventional plasma monitoring, film growth, and mechanical or wafer movement sensor devices. Recent needs have exposed inadequate monitoring of chamber conditions and expected mechanical movements. To these ends, the multi-sensor system may enable proactive monitoring and control of chamber conditions based on plasma, parasitics, HCD, particles, process drift and mechanical variations in the gap and/or around the pedestal or showerhead (and other use cases as described above), and support real-time analytics capability in a consolidated package.

At block 510, the method 500 may include determining a set of signals, from a plurality of sensors of semiconductor manufacturing equipment, to monitor during a process to be performed by the semiconductor manufacturing equipment. In some embodiments, block 510 may involve setting up data acquisition parameters for a particular process operation. The parameters may involve selection of two or more sensors from among multiple sensors available on a hardware tool. The sensors may be selected because, collectively, they are able to detect and/or characterize a particular event or condition within a process chamber. Some of these events or conditions are described herein as use cases and applications. In some implementations, block 510 may be performed once, during setup, and then not performed again, while other operations in the process are performed repeatedly.

In some embodiments, the plurality of sensors include multiple types of sensors. In some implementations, the plurality of sensors include one or more spatial sensors, one or more spectral sensors, and one or more temporal sensors. An example of a spatial sensor may be a camera.

According to some implementations, the one or more spatial sensors may include one or more cameras or one or more camera arrays, trained toward an interior of the semiconductor manufacturing equipment, and configured to obtain image data relating to the interior before, during, and/or after the process. In some implementations, the one or more spatial sensors may be configured to, during the process, obtain data relating to characteristics of plasma present within the interior. Such characteristics of the plasma may include intensity, location, whether it is parasitic, anomalies associated with it, etc.

An example of a spectral sensor may be an OES sensor. The OES sensor may be configured to detect one or more wavelengths of interest emitted by one or more species generated during the process.

An example of a temporal sensor may be a photodiode. The photodiode may be configured to detect variations in light intensity that occur over a time period of less than 1 milliseconds, including in the nanosecond and microsecond range.

In some implementations, these spatial, spectral, and temporal sensors may be a set of sensors with multiple sensor types combined into one consolidated package (or apparatus) that may be incorporated into a viewport (e.g., 900) or other window of the semiconductor manufacturing equipment (e.g., multi-sensor fabrication tool 800) and operated according to the descriptions provided below with respect to FIG. 8. Although the sensor types may be combined into one apparatus, they may not all be used. In some scenarios, the set of signals may be provided by all three sensor types. However, in some scenarios, the set of signals may be provided by two sensor types. For example, only a camera and an OES sensor may be used, or a camera and a photodiode may be used, depending on the application. In some implementations, the plurality of sensors may further include other sensor types, e.g., VI, pressure, or temperature sensors, to provide additional measurements.

In some implementations, the plurality of sensors may include two types of the one or more spatial sensors, one or more spectral sensors, or one or more temporal sensors. For example, in these implementations, the plurality of sensors may be a camera and an OES sensor only, without a photodiode.

At block 520, the method 500 may include obtaining measurements associated with the set of signals from the selected plurality of sensors. The measurements may be obtained during the process to be performed, and may be obtained via at least one spatial sensor, at least one spectral sensor, at least one temporal sensor, or a combination thereof, where the combination includes at least two types—spatial and spectral; spectral and temporal; spatial and temporal; or spatial, spectral, and temporal. The sensors may be used in series or concurrently in parallel to collect respective signals from the processing environment (e.g., a process chamber) and be primary, secondary, and/or tertiary indicators.

In some scenarios, the process to be performed by the semiconductor manufacturing equipment may include a detection of an unexpected amount of one or more species within an interior of the semiconductor manufacturing equipment. Here, the sensor types used to detect the unexpected amount of species may include the at least one spatial sensor and the at least one spectral sensor. In some scenarios, the process to be performed by the semiconductor manufacturing equipment may include an endpoint detection of a chamber clean of an interior of the semiconductor manufacturing equipment. Here, the sensor types used to detect the endpoint of the chamber clean may include the at least one spatial sensor and the at least one spectral sensor. In other scenarios, the process to be performed by the semiconductor manufacturing equipment may include any one or more of the use cases described elsewhere herein.

At block 530, the method 500 may include determining an indication of a state of the semiconductor manufacturing equipment based on a combination of data generated from the measurements associated with the set of signals (e.g., the measurements from block 520). Advantageously, the combination of data more accurately characterizes the state of the semiconductor manufacturing equipment than a signal from just one of the plurality of sensors as is done in conventional monitoring systems.

In some embodiments, the method 500 may include modifying a control parameter of the semiconductor manufacturing equipment based on the state of the semiconductor manufacturing equipment. Various changes to the control parameter may be made to enact changes to the processing environment, such as an amount of gas species flowing in or a rate thereof of a gas-specific line, clamping and de-clamping of a substrate from a pedestal (e.g., through electrical signals that change the voltage applied to an electrostatic pedestal), position of substrate, endpoint of chamber clean, timing of plasma strike, opening and closing of valves, shutdown of manufacturing process (e.g., based on excessive HCD) to prevent hardware damage, change in illumination, provision of alerts, provision of process-related data for manual review (e.g., to adjust process recipe, design of equipment, etc.), and other adjustments to effectuate the numerous use cases described above.

Otherwise, the state of the semiconductor manufacturing equipment may be confirmed, stored, or provided (e.g., displayed, recorded in a computer file, transmitted to another computing device) with no changes to the control parameter.

In some embodiments, a machine learning model may be implemented to improve accuracy of the output. The determining of the indication of the state of the semiconductor manufacturing equipment (block 530) may include performing a classification task or a regression task on at least a portion of the combination of data with the machine learning model to obtain the measurements associated with the set of signals configured to perform. For instance, in some cases, a regression model may be implemented with labeled data (e.g., previous measurements and correct labels) to enhance predictability and accuracy of measurements compared to those from individual sensors. In other cases, classification probability (e.g., whether detected plasma is parasitic, whether there is HF contamination, whether there is film growth) can be improved for the primary sensor (e.g., using a logistic model) when signal-to-noise reduces for a single sensor alone. The machine learning models utilized may be triggered simultaneously throughout the process or may be triggered at specific intervals depending on the use case.

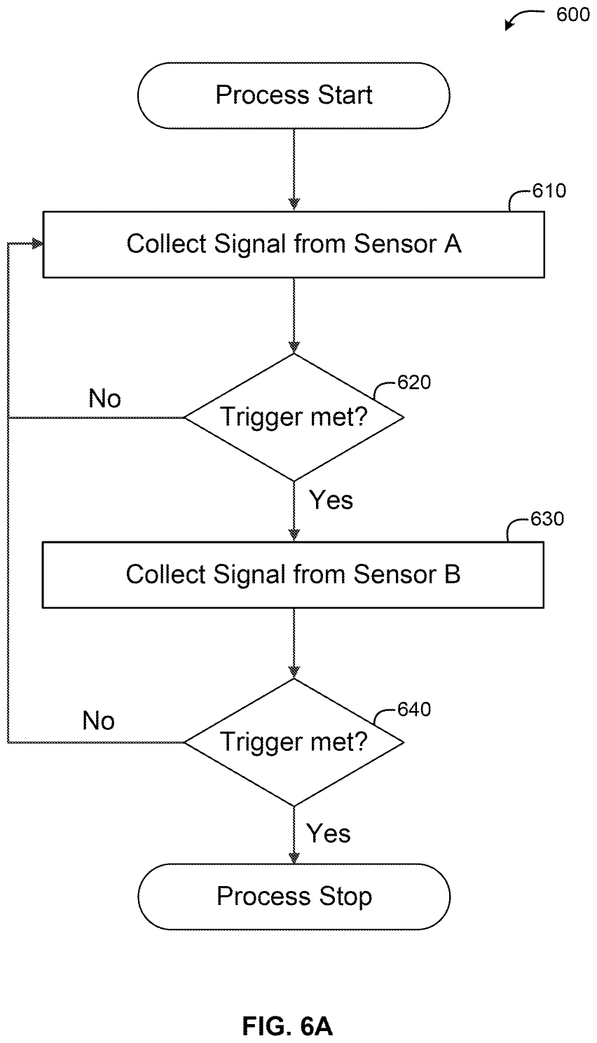

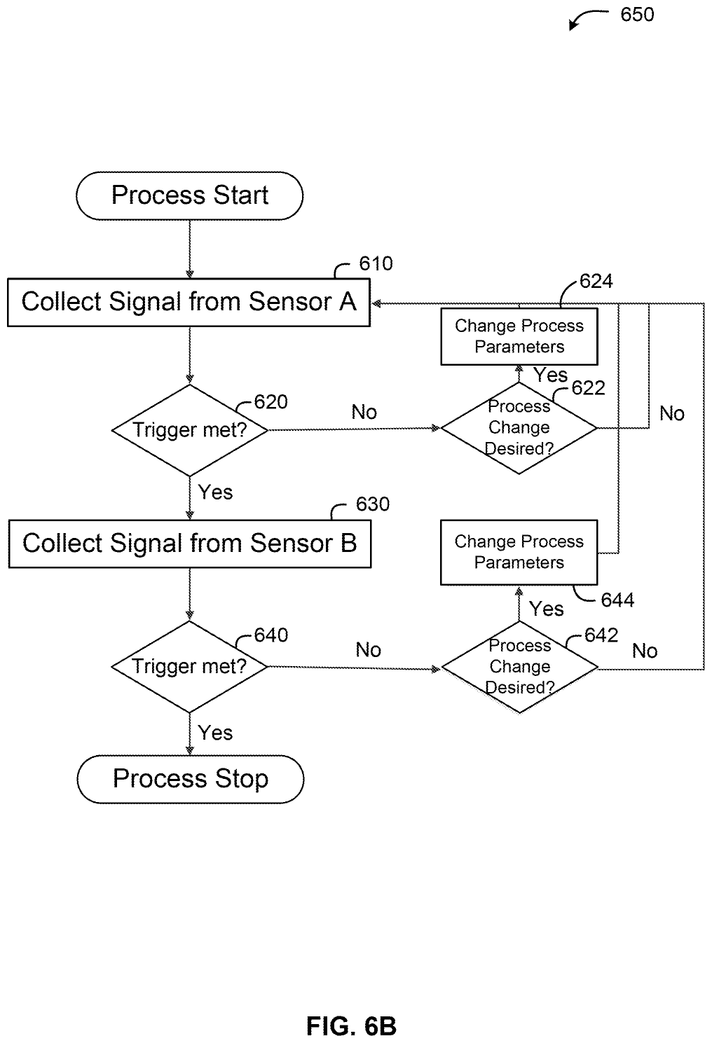

FIGS. 6A and 6B are flow diagrams illustrating methods 600 and 650 for determining a state of semiconductor manufacturing equipment, according to some embodiments. One or more of the functions of the methods 600 and 650 may be performed by or caused by a computerized apparatus or system. Structure for performing the functionality illustrated in one or more of the steps shown in FIGS. 6A and 6B may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system. A subsystem (e.g., 191) may be one example of the computerized apparatus or system. A process chamber may be another example of the computerized apparatus or system. Example components of a process chamber and a controller are illustrated in FIGS. 1A and 1B, and 13, respectively, and described in more detail elsewhere herein.

It should also be noted that the operations of the methods 600 and 650 may be performed in any suitable order, not necessarily the order depicted in FIGS. 6A and 6B. Further, the methods 600 and 650 may include additional or fewer operations than those depicted in FIGS. 6A and 6B to determine the state of the semiconductor manufacturing equipment.

Referring to FIG. 6A, at block 610, the method 600 may include obtaining a measurement signal via a first sensor. In some embodiments, the first sensor may be a spatial sensor (e.g., a camera), a spectral sensor (e.g., an OES sensor), or a temporal sensor (e.g., a photodiode).

At block 620, the method 600 may include determining whether a trigger condition corresponding to the first sensor is met. A trigger condition may be a condition that triggers a different operation such as collecting information from a different sensor, processing sensor signals from one or more sensors in a particular way, determining whether to make a real-time adjustment to a process, etc. In some examples, a trigger condition is a particular threshold for a sensor measurement obtained during a process performed by the semiconductor manufacturing equipment. An example may be a measurement that is lower than a prescribed threshold (determined for each type of sensor or the application or use case), which may be indicative of uncertainty about whether the measurement is a valid signal or noise that should be disregarded. A specific example as discussed herein may be a plasma conditions (e.g., intensity) within a process chamber (determined via in situ monitoring by a type of sensor described throughout the present disclosure, e.g., a camera), e.g., during the process performed by the semiconductor manufacturing equipment.

Another example of a trigger condition in a specific scenario may be an intensity shift from an OES sensor, as discussed elsewhere above. As further examples, gas compositions and shifts thereof (below or above a certain threshold), or a presence of an unexpected species (e.g., oxygen) may be detected by the OES sensor. These measurements may be primary indications for, e.g., determining a gas burst or an endpoint of chamber clean. Secondary or tertiary confirmation by at least one other type of sensor may be useful for confirmation (e.g., visual confirmation or additional information from another angle) of the primary indication by the aforementioned sensor examples.

To that end, if the trigger condition is met, the method 600 may proceed to block 630, which may include obtaining a measurement signal via a second sensor. The second sensor may be a type of sensor that is not the first sensor.

To illustrate, if the first sensor is a spectral sensor, the second sensor may be a spatial sensor or a temporal sensor. The spectral sensor (e.g., OES sensor) may be used predominantly to determine the chemical state of an interior of the process chamber, e.g., to determine how chamber clean is progressing. However, there may be portions that clean slowly, or the response from the spectral sensor may be weak and be sufficient to determine whether trace amounts of film that needs to be cleaned remains. This uncertainty in the response may be an example of a trigger condition (block 620). A camera pointed at the location of the trace amounts of film can provide secondary confirmation for clean endpoint. Hence, in this approach of multi-sensor synthesis, the OES sensor is a primary indicator in this scenario, and the camera is a secondary indicator for visual confirmation of portions that the system is chemically uncertain about.

However, in some implementations, the first and second sensor may be the same type of sensor. For example, the first sensor may be a camera at one wall of a process chamber pointed toward a top of a pedestal, and the second sensor may be a camera at an opposite wall pointed toward a bottom of the pedestal. In this way, a more complete visual view of the state of the interior of the process chamber may be obtained.

Otherwise, if the trigger condition at block 620 is not met, the method 600 may return to block 610.

At block 640, the method 600 may include determining whether a trigger condition corresponding to the second sensor is met. An example of a trigger condition here may be a measurement obtained by the second sensor which that meets or exceeds a prescribed threshold (determined for each type of sensor or the application or use case), which may be indicative of validity of the measurement.

If the trigger condition at block 640 is met, the measurement signal obtained via the second sensor may be used as a secondary confirmation of the measurement signal obtained via the first sensor (e.g., a weak measurement by the first sensor is validated). In some cases, where the second sensor may obtain a measurement of interest (e.g., plasma intensity can be derived from visual information or spectral measurements), the measurement signals obtained via the first and second sensors may both be used as separate measurements, or the measurement signal obtained via the second sensor may be used as the measurement in cases. If the trigger condition at block 640 is not met, the method 600 may return to block 610. However, in some implementations, the method 600 may return to block 630 instead to obtain an additional measurement signal from the second sensor.

Referring to FIG. 6B, in some embodiments, if the trigger condition is not met at block 620, the method may proceed to block 622, which may include determining whether a change to the process performed by the semiconductor manufacturing equipment is desired. In these embodiments, rather than obtaining additional confirmational measurement signal via the second sensor (block 630), the process can be changed because, e.g., the measurement signal obtained via the first sensor (block 610) without the trigger being met (block 620) still provided sufficient information to conclude that the state of the process chamber or the process has an anomaly or an undesirable condition requiring some modification to the process to remove, such as parasitic plasma, gas leak, gas composition shift, gas burst, electrical arc, etc. In some cases, it may be determined that the change to the process is desired based on other factors unrelated to an internal condition of the process chamber, such as time spent on the process.

If the change is desired, at block 624, the method may include changing one or more parameters of the process, and the method may return to block 610 to continue acquiring measurement signals via the first sensor. The process can be changed, paused, or aborted by changing the parameters of the process. According to various applications, an example of a parameter may be a power state of the process chamber or fabrication tool, where changing the power state can, e.g., at least partially shut down the fabrication tool so that the process can pause or stop. Another example may be a change in gas flow. An unexpected amount of gas or a presence of an unexpected species in the process chamber (e.g., a gas burst or a gas leak) may be reduced, or failure to introduce a sufficient amount of an expected gas may lead to increasing the expected gas. Another example may be an amount of etching performed during chamber clean. If the trigger condition indicates that a large amount of buildup has occurred, e.g., on a chamber wall, greater amounts of etching can be performed without damaging the chamber wall. Other examples of changes to the parameter (e.g., temperature, voltage, plasma timing, recipe condition, other operational parameter) will become apparent given the present disclosure.

If the change is not desired (e.g., because the state of the process chamber or process may benefit from additional confirmation from a secondary indicator), the method may return from block 622 to block 610 to continue acquiring measurement signals via the first sensor.

In some embodiments, if the trigger condition is not met at block 640, the method may proceed to block 642, which may include determining whether a change to the process performed by the semiconductor manufacturing equipment is desired. Here, the determination may be based on measurement signals obtained via the second sensor and/or the first sensor.

If the change is desired, at block 644, one or more parameters of the process may be changed, similar to block 624, and the method may return to block 610 to continue acquiring measurement signals via the first sensor. In some embodiments, the method may return to block 630 instead to acquire measurement signals via the second sensor, e.g., for further confirmation.

If the change is not desired, the method may return from block 642 to block 610 to continue acquiring measurement signals via the first sensor. In some embodiments, the method may return to block 630 instead to acquire measurement signals via the second sensor, e.g., for further confirmation.

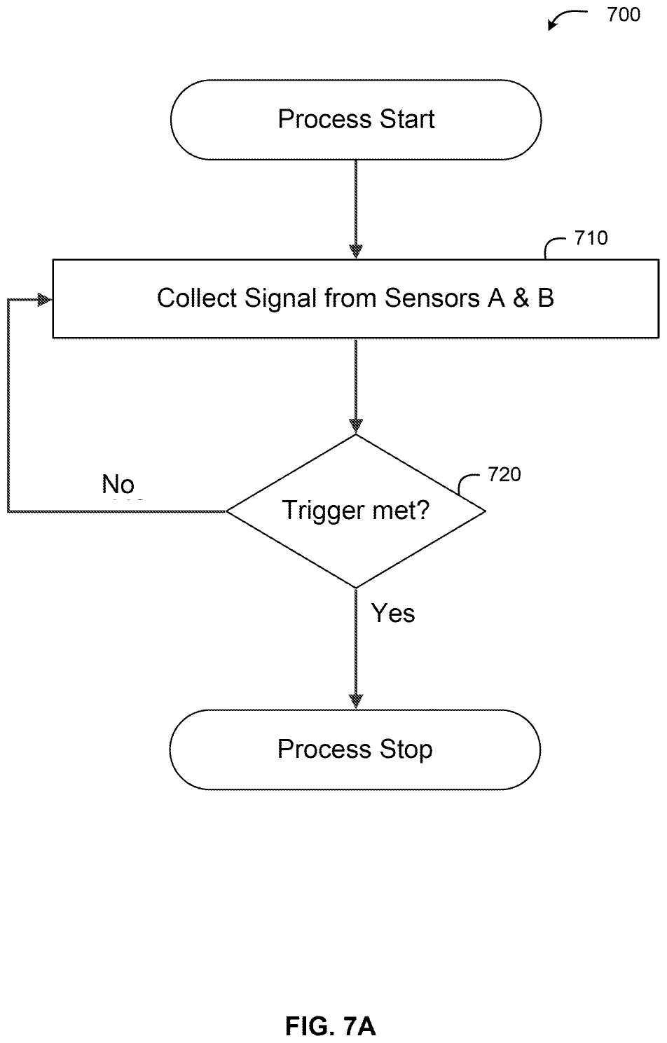

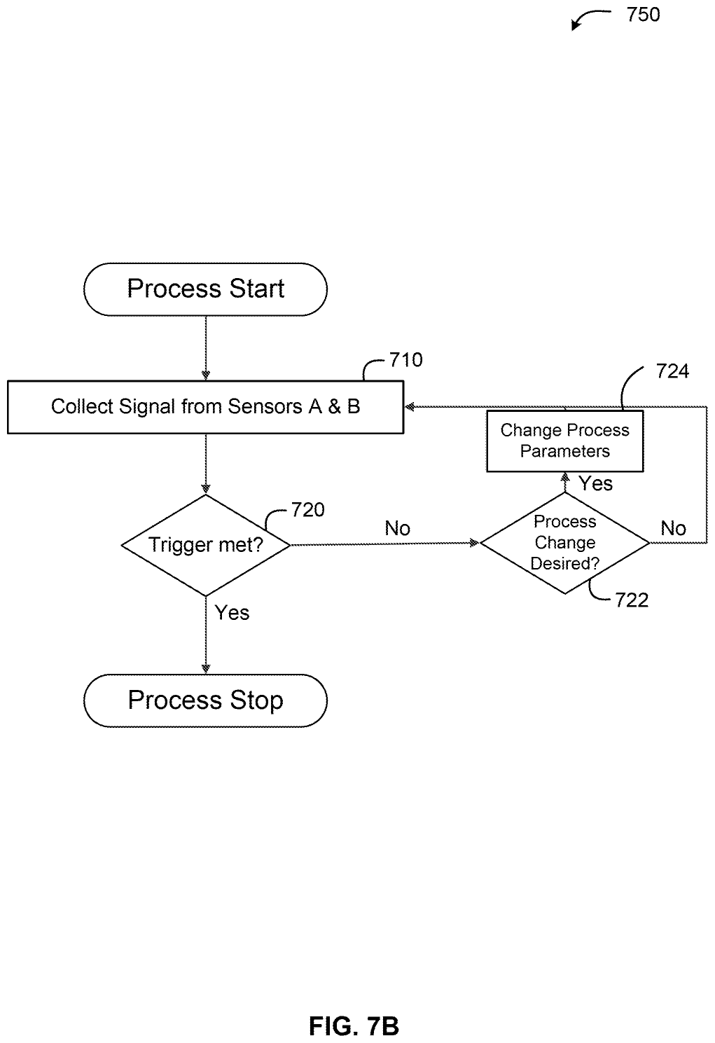

Methods 600 and 650 represent a serial collection and/or processing of information from two or more types of sensors, e.g., from a process chamber, a station, or other parts of a fabrication tool. Collection and/or processing of information may also be performed concurrently in parallel, as will be described below in the context of FIGS. 7A and 7B.

FIGS. 7A and 7B are flow diagrams illustrating methods 700 and 750 for determining a state of semiconductor manufacturing equipment, according to some embodiments. One or more of the functions of the methods 700 and 750 may be performed by or caused by a computerized apparatus or system. Structure for performing the functionality illustrated in one or more of the steps shown in FIGS. 7A and 7B may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system. A subsystem (e.g., 191) may be one example of the computerized apparatus or system. A process chamber may be another example of the computerized apparatus or system. Example components of a process chamber and a controller are illustrated in FIGS. 1A and 1B, and 13, respectively, and described in more detail elsewhere herein.

It should also be noted that the operations of the methods 700 and 750 may be performed in any suitable order, not necessarily the order depicted in FIGS. 7A and 7B. Further, the methods 700 and 750 may include additional or fewer operations than those depicted in FIGS. 7A and 7B to determine the state of the semiconductor manufacturing equipment.

Referring to FIG. 7A, at block 710, the method 700 may include obtaining a measurement signal via a plurality of sensors, which may include at least a first sensor and a second sensor. In some embodiments, the first sensor may be a spatial sensor (e.g., a camera), a spectral sensor (e.g., an OES sensor), or a temporal sensor (e.g., a photodiode). In some embodiments, the second sensor may be a spatial sensor (e.g., a camera), a spectral sensor (e.g., an OES sensor), or a temporal sensor (e.g., a photodiode). In some implementations, the second sensor may be of a different type than the second sensor. For example, the first sensor may be a spectral sensor, and the second sensor may be a spatial sensor.

In some embodiments, a measurement signal may be obtained via at least a third sensor. In some embodiments, the first sensor may be a spatial sensor (e.g., a camera), a spectral sensor (e.g., an OES sensor), or a temporal sensor (e.g., a photodiode). In some implementations, the first, second, and third sensors may each be of a different type. For example, the first sensor may be a spectral sensor, the second sensor may be a spatial sensor, and the third sensor may be a temporal sensor. However, in some other embodiments, different combinations of types of sensors may be utilized, e.g., two spatial sensors and one spectral sensor.

In some embodiments, one or more additional sensors may be utilized. Such additional sensors may include those that may acquire readings of voltage and current (VI), pressure, temperature, etc.

At block 720, the method 700 may include determining whether a trigger condition corresponding to the plurality of sensors is met. As noted above, a trigger condition may be a condition that triggers a different operation such as collecting information from a different sensor, processing sensor signals from one or more sensors in a particular way, determining whether to make a real-time adjustment to a process, etc.

If the trigger condition is met at block 720, the method 700 may stop. In some cases, the process chamber or fabrication tool may pause or stop operation in light of the trigger condition being met. This may be appropriate if, for example, continued operation is likely to damage the tool or wafers being processed in the tool. In some cases, the process chamber or fabrication tool may proceed to a different process or continue the process.

If the trigger condition at block 720 is not met, the method 700 may return to block 710 to obtaining a measurement signal via the plurality of sensors.

In some embodiments, however, referring now to FIG. 7B, if the trigger condition at block 720 is not met, the method 700 may include, at block 722, determining whether a change to the process performed by the semiconductor manufacturing equipment is desired. Examples of determining the desirability of the change to the process are described above with respect to block 622.

If the change is desired, at block 724, the method may include changing one or more parameters of the process, and the method may return to block 710 to continue acquiring measurement signals via the plurality of sensors. Examples of the parameter are described above with respect to block 624. The process can be changed, paused, or aborted by changing the parameters of the process.

If the change is not desired, the method may return from block 722 to block 710 to continue acquiring measurement signals via the plurality of sensors.

In these ways, two or more different types of sensors may collectively obtain information, rather than serially (e.g., depending on a trigger condition), from a process chamber, a station, or other parts of a fabrication tool.

### Apparatus

### Multi-Sensor Capabilities

FIG. 8 is a block diagram illustrating a hardware configuration for a multi-sensor fabrication tool 800 (e.g., multi-station fabrication tool 150 or 182) implementing a combined set (or “suite”) of sensors utilizing multiple types of sensors for manufacturing equipment 850, according to some embodiments. In some embodiments, the multi-sensor fabrication tool 800 may include a combined set of sensors 810 associated therewith, e.g., internally or externally disposed or connected with a controller (e.g., system controller 190) or a subsystem (e.g., subsystem(s) 191) of the multi-sensor fabrication tool 800. Each of the sensors may send or receive signals from the controller or subsystem based on information obtained from, e.g., the manufacturing equipment 850. In some embodiments, the combined set of sensors 810 may be packaged into a sensor package 810 interfacing with a viewport or window of a process chamber, such as a process chamber of a multi-station fabrication tool 150 or 182. According to different implementations, one or more sensor packages may be available per process chamber or station.

In some implementations, the multi-sensor fabrication tool 800 may include a plurality of sensor types, specifically two or more types from one or more spatial sensors 812, one or more spectral sensors 814, or one or more temporal sensors 816. These sensor types may be packaged into one set of sensors 810 and may not be customized for one particular application usable with a given sensor type, although the set of sensors 810 may be combined in different ways depending on the implementation. This “omnibus” approach may increase usability with multiple applications (and less customizations) and thereby reduce production costs, along with improved machine availability (MA, how much unit time a machine is available for processing, e.g., a wafer), improved green-to-green (GtG) periods (reduced downtime, or “red,” periods) and throughput, and improved wafer-to-wafer (WtW) uniformity and wafer quality, as well as greater precision, stability, and matching from combined utilization of different types of sensors that are conventionally used independently.

In various embodiments, a sensor package 810 may include one or more physical hardware features that enable the capabilities of multiple sensors used in conjunction as described herein. In some implementations, the sensor package 810 may be contained by a housing having at least one principal dimension (e.g., major axis, diagonal axis, height, diameter, radius, or other geometry-dependent feature) that is not greater than about 10 inches. Other dimensions may be possible according to needs and capabilities of a particular sensor package that may have different ones of the components described herein. An example of a housing may be housing 1001 as discussed below with respect to FIG. 10. The housing may be shaped so as to house at least one spatial sensor 812, at least one spectral sensor 814, at least one temporal sensor 816, or according to variations, a combination of at least two of the foregoing types of sensors. In some implementations, the housing may include at least one interface allowing the hardware to attach to a wall of a process chamber. An interface may be a physical interface that allows adhesion or interlocking, or involves other mechanisms or structures of attachment to the wall. In some cases, the wall may be part of a heat shield (e.g., 1002, 1003 of FIG. 10) or vice versa. In some implementations, the housing may also include a wired or wireless communication interface and/or a power interface (e.g., cables), or structure that can route or house such communication or power interfaces. The sensor package 810 may include a structure to affix some or all of the above components, such as a printed circuit board (PCB) or printed wiring board (PWB). In some implementations, the sensor package 810 may further include an illumination source (e.g., at least one LED), on-board processing capability, filters (e.g., optical), and/or other components mentioned with respect to FIGS. 9 and 10 below.

In particular implementations, two of the foregoing sensor types may be implemented with the multi-sensor fabrication tool 800. In particular implementations, all three of the foregoing sensor types may be implemented with the multi-sensor fabrication tool 800. An example of a spatial sensor 812 may include (but are not limited to) a camera or another image capture device configured to acquire visual or optical information. An example of a spectral sensor 814 may include (but are not limited to) an OES sensor or a spectral reflectometer device. An example of a temporal sensor 816 may include (but are not limited to) a photodiode or another type of light sensor. In some implementations, one or more other sensors (e.g., VI, pressure, temperature) may be included in addition to the foregoing plurality of sensor types.

In various embodiments, the set of sensors 810 may be used to obtain spatial, spectral and/or temporal information that when analyzed can provide a better understanding of the state of the system (e.g., observations of processes of multi-sensor fabrication tool 800) as well as provide opportunities for control and adjustment or management of process parameters. The two or more types of sensors (including use cases with three types of sensors and/or additional types of sensors, e.g., temperature sensors) may be respectively considered a primary sensor or indicator, a secondary sensor or indicator, a tertiary sensor or indicator, a quaternary sensor or indicator, etc.

In this context, a primary sensor may collect data that is used to detect or measure or otherwise obtain signals (e.g., from radiation) from a process, where the signals can independently determine the presence or change to the process without any other sensors (e.g., secondary, tertiary). A secondary sensor may collect data that can assist with obtaining signals that the primary sensor may not fully or accurately be able to acquire. For example, in some cases, the OES sensor may capture a first portion of a process environment, but a camera may capture a second portion. Using illustrative example numbers, one sensor may be able to capture 70% of the information, and another sensor may be able to capture the remaining 30% of the information by capturing additional perspectives or types of signals. For instance, even though an OES sensor as a primary sensor may detect films left on the back of a pedestal, a camera may be able to visually detect potential presence of film on the side or a top of the pedestal. Without the camera, the OES sensor may not have detected the film on the top of the pedestal. As another example, the OES sensor may be unable to detect any presence of film because of insufficient amounts of trace material left on the walls, indicating to a conventional fabrication tool that cleaning need not be performed. However, a camera may be able to sense the film and provide an indication that film was detected. As another example, an OES sensor may be able to detect sufficient amounts of material on the walls but with uncertainty regarding the presence of film. A camera may provide secondary indication that provides confirmation, e.g., (i) only when it is determined that an amount of film was detected but insufficient, which may be a trigger condition for activating a spatial sensor such as a camera to confirm the presence of film; or (ii) in parallel and concurrently with the OES sensor to provide a strong combined indication. In these ways, primary and secondary sensors may be used together to obtain a more complete state of a process or a byproduct thereof. In this context, a tertiary sensor may be used as a redundant sensor to act as a backup, e.g., should the primary or the secondary sensor fail. The tertiary sensor may provide at least partial information in case the first or second sensor is not operational. This third sensor may only act as a temporary solution, e.g., until the system is taken offline for maintenance. In some cases, all three types of sensors may be used to acquire primary, secondary, and tertiary indications.

In some implementations, combining measurements from the primary sensor and the secondary sensor may improve the accuracy and/or precision of the measurements, or obtain additional relevant information (e.g., use temporal sensing to detect chamber arc, and use spatial or spectral sensing to determine location or source). The tertiary sensor or beyond may be a redundant sensor used as a backup in case one of the primary or the secondary sensor fails, and not used in measurements. In some implementations, however, measurement data from the tertiary sensor or beyond may be used in conjunction with the primary sensor and/or secondary sensor to further improve accuracy and/or precision of the measurements of interest.

One specific embodiment of the disclosed system (e.g., the multi-sensor fabrication tool 800) combines one or more cameras to provide spatial information in visible and IR spectra, one optical emission spectrometer (OES) for spectral sensing in UV, visible, and IR spectra, one photodiode for rapid temporal sensing of events, and one or more illumination sources to improve detection capabilities. The data obtained from these sensors is combined to produce a stronger signal that allows, e.g., an informed automated response in the system addressing one of the many use cases described below.

In some cases, a machine learning model or algorithm may be used to improve accuracy of the output. For instance, in some cases, a regression model may be implemented with labeled data (e.g., previous measurements and correct labels) to enhance predictability and accuracy of measurements compared to those from individual sensors. In other cases, classification probability (e.g., whether detected plasma is parasitic, whether there is HF contamination, whether there is film growth) can be improved for the primary sensor (e.g., using a logistic model) when signal-to-noise reduces for a single sensor alone. The machine learning models utilized may be triggered simultaneously throughout the process or may be triggered at specific intervals depending on the use case.

### Viewport Components

FIG. 9 illustrates a diagram of a cross-sectional view of an example viewport 900 of a fabrication tool (e.g., multi-sensor fabrication tool 800), the viewport 900 having a set of sensors (e.g., 810) associated therewith, according to some embodiments. The set of sensors includes multiple types of sensors, e.g., two or more of the aforementioned spatial, spectral, or temporal sensors (or additional sensors such as VI, temperature, pressure, etc.). The viewport 900 may include spatial, spectral, or temporal sensors (three types of sensors) and be integrated into a process chamber of a station of the fabrication tool.

In some embodiments, the viewport 900 may include a spatial sensor such as a camera 901. The camera 901 may be placed for optimal view of the process chamber to monitor ongoing processes within. In some implementations, the fabrication tool, a given station, or process chamber may include multiple cameras, and the camera 901 shown in FIG. 9 may be one of the multiple cameras. Similarly, the fabrication tool, a given station, or process chamber may include multiple viewports, and the viewport 900 may be one of the multiple viewports. According to different implementations of the fabrication tool, the camera(s) 901 or viewport(s) having the camera(s) 901 may be placed in the manner depicted in FIG. 2 or 3, or in various locations of a chamber wall. The camera(s) 901 may have a cover or shutter that can be kept open or closed which protects the lens. In some embodiments, the camera(s) 901 may be movable in a direction such that the camera 901 is able to obtain optical information from different perspectives, e.g., of a face of a showerhead or a surface of the pedestal. The movement may be a translation movement in a direction that is vertical 910, horizontal 911, or diagonal 912 (at an angle relative to vertical or horizontal), these directions being relative to one another rather than having an absolute directional bearing. In some embodiments, the camera(s) 901 may be tiltable in azimuth and elevation angles while staying in the same position relative to the viewport 900.

In some embodiments, the viewport 900 may include a spectral sensor (such as an OES sensor configured to obtain spectral measurements as described herein) and an OES collimator 902, which may narrow beams of radiation waves emitted from within the process chamber. The OES collimator 902 may have a protective cover or shutter that can be kept open or closed. In some embodiments, the viewport 900 may include a temporal sensor such as a photodiode 903 configured to obtain measurements as described herein. In some embodiments, the viewport 900 may include a lighting system or one or more illumination sources, such as one or more LEDs 904.

In some embodiments, the above components may be packaged into a set of sensors (such as that described with respect to FIG. 8) at the viewport 900 of the fabrication tool. The viewport 900 may be disposed relative to other components of the fabrication tool, such as a showerhead 905, a focus ring 906, a pedestal 907, and/or an RF liner plate 908.

FIG. 10 illustrates a diagram of an external perspective view of a chamber 1000 for the example viewport 900 of the fabrication tool, according to some embodiments. In some embodiments, chamber 1000 may include a housing 1001, which may contain one or more components of FIG. 9 as described above, e.g., a camera 901, a spectral sensor, an OES collimator 902, a photodiode 903, one or more LEDs 904, or other components as described above with respect to the sensor package 810. The housing 1001 may take various shapes (e.g., circular as shown in FIG. 10, polygonal (e.g., square), or at least partially conical with angular sides and/or flat top surface) and protrude from an exterior, e.g., an external side of a wall of a process chamber of the fabrication tool. In some implementations, housing 1001 may consider material selection and parts geometry for illumination sources to avoid reflection into the spatial sensor. For example, the components inside the housing 1001 may have a matte or other non-reflective surface to prevent inaccurate illumination of the interior of the fabrication tool. As noted above, the housing may have some principal dimension of that is not greater than about 10 inches. As noted above, the fabrication tool or its process chamber may include multiple viewports. These multiple viewports may house the one or more components but not necessarily the same ones. For example, a first viewport may have a camera but not a photodiode, while a second viewport may have a photodiode but not an OES sensor. The configuration may depend on whether other views available through viewports or windows has sufficient field of view. Multiple such housing 1001 may be available to be used with the fabrication tool, or with a process chamber (e.g., implemented as multiple sensor packages 123 and 125, multiple sensor packages 196, 197 and 198, or multiple sensor packages 394 and 394′).

In some embodiments, the housing 1001 may include various physical components and structures that support and stabilize the sensors. According to implementations, such structures may include a viewport bezel, an LED holder, a mounting plate, a heatsink, data connectors and power cables, a printed circuit board (PCB) or printed circuit board assembly (PCBA), a lens, and/or an outer cover. In some implementations, a heat shield or a radiation filter (e.g., UV filter) may be included or excluded in some components. Other standard structures such as rings and fasteners, communication interfaces (e.g., Universal Serial Bus (USB) adapter), wire passthroughs, fins, reflective surfaces, ventilation holes, fans, and coatings may be used as well. Sensors or sensor assemblies (e.g., OES collimator assembly, photodiodes, cameras) may be positioned, assembled, or otherwise positioned among the foregoing structures, and the structures may be constructed using materials of choice (e.g., aluminum), in various configurations as would be evident to those having ordinary skill in the relevant art.

In some embodiments, the exterior of a process chamber may include a first heat shield 1002 (e.g., top heat shield) and/or a second heat shield 1003 (e.g., bottom heat shield). Data connectors and/or power connectors may be placed under the first heat shield 1002 or the second heat shield 1003. For example, a fiber connector physical contact (FC-PC) adapter for the photodiode 903 may be run beneath a heat shield. The heat shields 1002, 1003 may house at least portions of other components. For instance, a viewport may be through the second heat shield 1003, as illustrated in FIG. 10. In other embodiments, the viewport and one or more of its components (e.g., a camera) may be positioned between the first and second heat shields 1002, 1003. In fact, the viewport may be placed in any location appropriate for the fabrication tool or an application.

In some embodiments, thermal management is also employed with the viewport 900 or housing 1001 by use of passive and/or active cooling system to ensure reliable operations. Other UV, thermal, and RF safety management components and features may be included with the housing 1001.

### Example Use Cases and Applications

There are numerous examples of applications and uses for multiple types of sensors in a process chamber. Some applications employ two or more sensors, with at least two of the sensors being some combination of a spatial sensor, a spectral sensor, and a temporal sensor. In some applications, one of more such sensor is used in conjunction with a different type of sensor such as a current and/or voltage sensor at a location in a process chamber (e.g., of a fabrication tool 800). Various applications involve using a combination of sensors to detect and/or characterize a condition or event occurring in a process chamber. If such event or condition is anomalous, it may require a particular response such as pausing operation, replacing a component, or changing a process condition. Various examples of conditions and events follow.

One example of such event is a plasma intensity variation within a process chamber. Such variations may have temporal, spectral, and/or spatial features. For the example, the variation may have spike or pulse like temporal structure characterized by a duration, leading edge shape, etc. Such variation may be associated with a condition or event in a plasma generator, a physical structure, a process gas flow, etc. within the process chamber. A temporal sensor such as a photodiode may provide information allowing the temporal shape of a plasma intensity variation to be fully or partially characterized. Such variation may additionally have a spectral composition that is associated with a particular gas or other material that is ionized in the plasma. Information collected by a spectral sensor such as an OES sensor can help elucidate the material that is associated with a plasma intensity variation. Further, such variation may be located at a particular region or in multiple regions within a process chamber. The location may indicate a particular component or multiple components that are responsible for the plasma intensity variation. To this end, information collected by a spatial sensor such as a camera sensor may allow a system or a process engineer to focus one or more components associated with a plasma intensity variation.

A related example of an event or condition is the presence of a parasitic plasma in a process chamber. A parasitic plasma typically has a consistent location, which can be determined with a spatial sensor. It may also a spectral composition, which can be determined with a spectral sensor. Using information gleaned from both a spatial sensor and spectral sensor, a system can determine the location, intensity, and/or ionized gases of parasitic plasma. With this information, affected components can be replaced, cleaned, or modified and/or process conditions can be adjusted.

Another example of an event in a process chamber is an RF pulse. As an example, such pulses may be used to generate a pulsed plasma. An RF pulse and an associated plasma pulse may have various signatures such as light emitted at a particular location, having a particular spectral composition, having a particular temporal profile, having a particular voltage, etc. Collectively such information allows a system to detect and/or characterize RF pulses within a process chamber. And such information may be captured using a plurality of sensors such as a spatial sensor (e.g., a cameral sensor), a spectral sensor (e.g., an OES sensor), a temporal sensor (e.g., a photodiode), a voltage/current sensor, or any combination thereof. In certain embodiments, to detect and/or characterize RF pulses within a process chamber lasting over a certain threshold (e.g., over 35 ms), a system employs a spatial sensor as a primary indicator, a spectral sensor as a secondary indicator, and a temporal sensor as a tertiary indicator. In some implementations, VI sensors may also be used to acquire voltage and/or current data to supplement the characterization of RF pulses.

Another example of an event in a process chamber is a gas composition shift. This may be due to various causes, some of which are expected and some of which are unexpected. Examples include introduction of new gases, failure to introduce expected gases, and leaks. Gas composition shifts may change certain characteristics of a plasma in a process chamber. Such changes may have spatial and/or spectral characteristics that can be detected by appropriate sensors. For example, a shift in the intensity of a plasma at the location of process gas input or at the location of a leak may be detected with a spatial sensor such as camera. Additionally or alternatively, a shift in the spectral composition of a plasma (caused by a shift in gas composition) may be detected with a spectral sensor such as an OES sensor. As an example, to detect and/or characterize a shift in gas composition within a process chamber, a spectral sensor may be used as a primary indicator, and a spatial sensor may be used as a secondary indicator. In other implementations, a spatial sensor may be the primary indicator, and a spectral sensor may be the secondary indicator.

Another example of an event in a process chamber is an electrical arc in a chamber. Arc may damage chamber components such as showerheads or pedestals, introduce defects to wafers, rob the system of power used to produce plasmas, etc. To detect chamber arcs within a process chamber, a temporal sensor (e.g., diode) may be used as a primary indicator (it detects the onset of an arc by capturing a high intensity light emission), and a spatial sensor (e.g., a camera) may be used as a secondary indicator to localize the arc. In some implementations, VI sensors may also be used to acquire voltage and/or current data associated with electrical arcing. In some applications, detection of an arc and its location may facilitate troubleshooting of defect clusters on wafers. For example, if defects cluster appear disproportionately on one area of a wafer, and sensor information suggests that there is an arc in the vicinity of the cluster, the defects may be mitigated by addressing the underlying problem causing the arcing.

Chamber clean endpoint: As another example, accurate detection of chamber clean endpoint may be of interest when operating process chambers. Processes performed within a process chamber, such as deposition of a conformal material film onto a substrate using, e.g., chemical vapor deposition (CVD) processes, may result in film deposition not just on the substrate, but also on various chamber surfaces as a byproduct of the processes. Over time, unwanted deposition build-up on chamber surfaces leads to particulates and potential contamination, which can negatively impact wafer yield. Process chambers are cleaned periodically to remove such build-up of byproduct particulates. Removal of chamber deposition can be done by, e.g., reacting films of trace byproducts with reactive gas (e.g., radical fluorine) to generate silicon tetrafluoride (SiF) which can then be removed from the chamber. The optimum clean time for a given chamber varies depending on many factors including the type of deposited material, temperature, pressure, reactive gas delivery, etc. It would be advantageous to determine the endpoint of chamber clean to prevent overcleaning by, e.g., reactions with the surfaces themselves.

Chamber clean may be performed (e.g., periodically after precursor chemicals introduced into a process chamber are deposited onto a substrate and/or internal surfaces) to maintain the lifetime of the pedestal and/or improve performance of deposition or other processes. However, invariably, as noted above, there is gradual and incremental buildup of trace amounts of chemical byproducts on components of the process chamber, e.g., walls, pedestals, or showerhead. It is desirable to detect the clean endpoint to stop the etching process such that buildup is fully removed but not beyond that (not etching the wall or pedestal itself). Current approaches to chamber clean involve timed cleans (which does not account for system or process variability and/or changing accumulation based on differing processes) or usage of IR-EPD. IR-EPD looks for a certain voltage and slope of the signal and adds an overetch step. IR-EPD may result in significant etching in some regions of a chamber, reducing the lifetime of the pedestal, e.g., caused by AlF₃ formation.

In some embodiments of the present disclosure, a spectral sensor (e.g., OES sensor) may act as a primary sensor to indicate clean state. As clean progresses, the OES signal in the light collection region may be diminished to the point where small films still left, e.g., on the back of the pedestal, may not make any direct impact on plasma response captured by OES. If this sensor is used in isolation, then the system may leave a small amount of film behind, and repeated cycles may result in particle issues. Systematically adding an over-etch similar to the current approach may risk reducing the life of the pedestal by formation of excess reaction byproducts, e.g., AlF₃. However, OES used in conjunction with a spatial sensor (e.g., camera) pointed at the slowest etched part (e.g., concurrently or at different times relative to spectral sensing) can provide a secondary trigger to indicate the clean is complete without significant overetch.

Process engineering (e.g., unexpected gas detection): As another example use case, consider a gas leak scenario in which an unexpected gas is introduced in the system (e.g., a chamber of the multi-sensor fabrication tool 800) or a burst of gas more than what was expected occurs during a process step. Process performance checks are usually done by visually verifying how the plasma behaves a certain way when viewed through a viewport, based on sensor response to one of hundreds of correlated channels, or (most often) through performance on a wafer after process is completed. Conventional approaches do not provide an instantaneous response. Moreover, subtle system drifts may not be easily comprehended by visual inspection in fast-changing systems; plasma dynamics are in the order of μs-ms. Constant monitoring of correlated channels is also not feasible without (automated) monitoring systems, and subtle changes may not be accurately capturable with the currently used sensors (visual) or may be deemed as noise in the system. A reliable indicator of process change is the impact a certain recipe has after process. Post-process metrology can indicate if a system state has changed based on the response of properties on the wafer (thickness, RI, etc.). However, not all wafers are measured. These does not make real-time control feasible and can result in undesirable wafer scrap.

In some embodiments of the present disclosure, a spatial sensor 812 (e.g., camera) may be used to monitor the plasma during a process step. Visual models may indicate there is a change in peak or average intensity within a region of interest. While instantaneous warnings or alerts can be generated or displayed by system, the cause of the impact and any corrective action can only happen after a product (e.g., wafer) is completed to determine a state of the system completely with gas flows, local pressure, power, etc. This may result in one or more wafer quality issues where the wafer may be evaluated for lower quality or yield and/or completely scrapped. Real-time control of the system may be enhanced when the camera signal is accompanied with an OES signal indicating that a certain species and their deposition rate may have increased. Thus, deposition time or number of cycles can be reduced in real time to compensate for the excessive deposition rate at a given step (or steps) of the process.

Further use cases are possible with the multi-sensor fabrication tool 800 using a combined set of sensors 810.

For instance, the combined set of sensors 810 may enable detection of parasitic plasma, wherein plasma intensity shift in two (or more) different regions of the process chamber (e.g., main cavity, edges or stem of pedestal or showerhead) may be monitored using a camera as a primary indicator and an OES sensor as a secondary indicator. In some implementations, this can be done by defining a plasma contour (which may involve an additional compute cycle), Fourier transforming from time domain to frequency domain (>500 Hz associated with ignition failures or particles), determining which frequency plasma flickering occurs, and looking for abnormal shifts in intensity that may be related to flickering.

In some implementations, process chambers and plasma may be monitored for hollow cathode discharge (HCD), e.g., at the regions of lift pins defining a storage location for a substrate or wafer. More specifically, in one example process, a camera may be used as a primary indicator to mark areas where lift pins are located, monitor parasitic plasma in the vicinity (e.g., within a prescribed distance) of lift pins for indication of improper position, and capture the change in plasma intensity over time.

As another example, hardware deformation may be detected using a camera as a primary indicator. In some cases, showerhead deformation or relative gap profile change may be determined based on changes in plasma shape. In addition, hardware damage may be prevented by monitoring for HCD in the main plasma. In some cases, the number of HCD may indicate whether to continue with the process. For example, if more than 10 HCDs, the process may be stopped and/or the system may be shut down, and if fewer than 10 (or other quantity of) HCDs, the system may initiate a “soft” shutdown (e.g., deactivate non-essential modules or processes).

As another example, film flaking may be detected and prevented by monitoring film growth or flacking in different regions of the process chamber. More specifically, in one example process, a film may be grown in a process chamber using, e.g., one of various chemical vapor deposition (CVD) processes, and a camera may be used as a primary indicator to monitor film growth in the chamber or on the wafer.

As another example, process diagnostics may be performed. Using a spectral sensor as a primary indicator, process gas composition may be measured, gas connections may be confirmed, purge timing may be assessed, and/or other related applications may be performed. One example approach to this may be to strike plasma, and then measure a rate of change in spectral measurements associated with gas-specific lines.

Another example is to detect air leaks or gas leaks. One example approach to this may include striking plasma in flowing gas, shutting off all valves, and measuring a change in N₂ emissions using a spectral sensor as a primary indicator. In some implementations, a spatial sensor may spatially isolate it, and a combination of the spatial sensor and the spectral sensor may enable detection of where the leak has occurred and of what species.

Other examples of use cases and applications of a set of sensors (e.g., of a multi-sensor fabrication tool 800) may include plasma spatial variation (primary spatial sensor), gas impurity sensing (primary spectral sensor), wafer placement (primary spatial sensor), detection of droplets (primary spatial sensor) from rinse processes to allow the substrate to dry, determination of plasma health or quality (spectral and spatial sensors), chamber-to-chamber or station-to-station transition matching (spectral, spatial, and temporal sensors), alerting a spatial sensor (e.g., camera) or a controller if information change (e.g., within a process environment) occurs faster than the frame rate of the camera (primary temporal sensor), determination of plasma ignition time (primary temporal sensor) where byproducts may not be effectively purged and may result in ignition delays or changes to the ignition profile, and reconstruction of location and quality of plasma uniformity (spectral and spatial sensors), and other applications and capabilities whose accuracy, strength, or completeness of signals detected can benefit from multiple sensor types. Using a combination of all the sensors, it is possible to detect pulses at over 100 samples per second.

In each of the above use cases and approaches, any types of spatial, spectral, or temporal sensors not explicitly mentioned may be used as a secondary indicator and/or a tertiary indicator, along with other sensors (e.g., VI, temperature, pressure) and/or illumination sources associated with a processing environment.

In some cases, primary and secondary indicators may be reversed. That is, even if the primary indicator is able to independently obtain measurements without the secondary indicator, the secondary indicator may be used as the primary indicator (either independently or partially able to obtain measurements). Some configurations or packages of sensors for a fabrication tool may not include the desired primary indicator. For example, the set of sensors 810 installed to a fabrication tool may not include a photodiode, but the process may call for chamber arc detections suitable with rapid light detection, for which a photodiode would be the primary indicator. In such cases, a camera may be able to detect arcs, at least ones that last at least in the millisecond range, and as such, the camera may be the primary indicator instead.

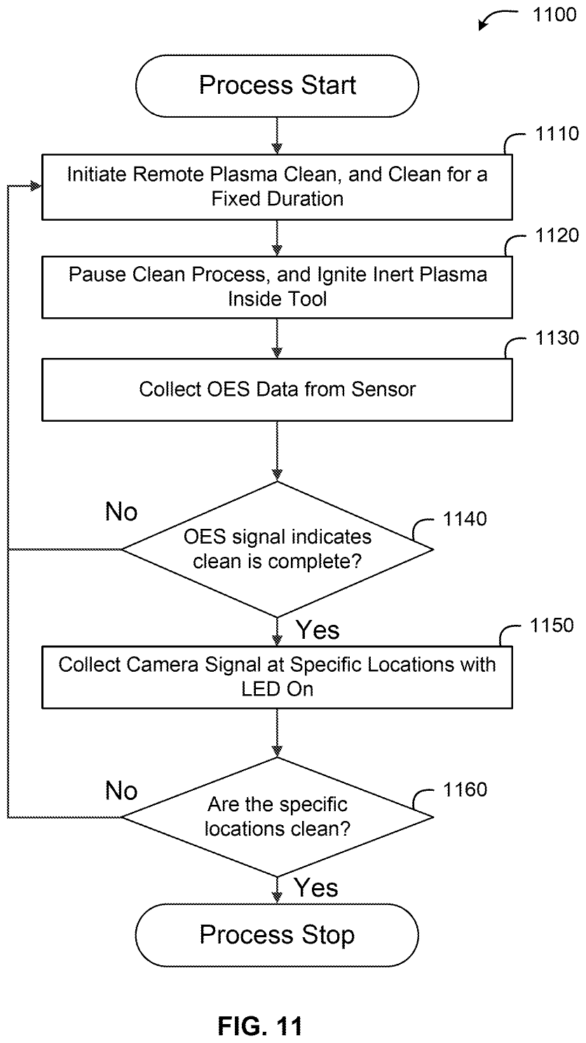

FIG. 11 is a flow diagram illustrating a method 1100 for multi-sensor determination of a process chamber clean endpoint, according to some embodiments. One or more of the functions of the method 1100 may be performed by or caused by a computerized apparatus or system. Structure for performing the functionality illustrated in one or more of the steps shown in FIG. 11 may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system. A subsystem (e.g., 191) may be one example of the computerized apparatus or system. A process chamber may be another example of the computerized apparatus or system. Example components of a process chamber and a controller are illustrated in FIGS. 1A and 1B, and 13, respectively, and described in more detail elsewhere herein.

It should also be noted that the operations of the method 1100 may be performed in any suitable order, not necessarily the order depicted in FIG. 11. Further, the method 1100 may include additional or fewer operations than those depicted in FIG. 11 to determine the clean endpoint.

At block 1110, the method 1100 may include initiating a process chamber clean process. In some embodiments, the clean process may include initiating a remote plasma clean, and cleaning at least portions of a process chamber of a fabrication tool for a fixed duration. Various approaches may be taken to initiate the clean process as is known in the relevant art.

At block 1120, the method 1100 may include pausing the clean process and igniting an inert plasma inside the fabrication tool. Pausing may be useful in preventing overetch (or cleaning beyond the byproducts that are present, e.g., as a film) of the interior of the process chamber, e.g., a wall, a component, or other surface within the process chamber. Overetch may result in damage, and determining the least-damaging endpoint can advantageously prolong the usability and life of the equipment.

At block 1130, the method 1100 may include collecting spectral information via a spectral sensor (e.g., at least one OES sensor). The spectral sensor may be part of and incorporated into a sensor package having multiple types of sensors including the spectral sensor and at least one other type (e.g., spatial sensor). In some implementations, the sensor package used may further include at least another type of sensor (e.g., temporal sensor). Spectral information may indicate the presence of certain materials and byproducts from the interior of the process chamber. Presence of different trace species may result in different wavelengths being emitted and detected. Exposure of a surface from cleaning may result in a corresponding wavelength being emitted and detected, because the surface is made of a different material (e.g., aluminum) from the process byproducts.

At block 1140, the method 1100 may include determining whether the spectral information is indicative of the clean process being complete. In some cases, the spectral information may not change or change to an insufficient degree, which may indicate that the chamber clean is incomplete, as the wall or other interior component has not yet been exposed from the clean process. In these cases, more cleaning (e.g., etching) may need to be performed, and the method 1100 may revert to block 1110. In some cases, the spectral information (e.g., wavelengths detected) may shift to indicate that the surface being cleaned is exposed rather than still coated with a film of previous process byproducts. In these cases, the method 1100 may proceed to block 1150.

At block 1150, the method 1100 may include collecting spatial information at specific locations. This may be used for secondary, confirmation purposes in conjunction with the spectral information as a primary indication. In some embodiments, the spatial information may be collected via a spatial sensor (e.g., at least one camera). The spatial sensor may be part of and incorporated into a sensor package having multiple types of sensors, e.g., the same sensor package that incorporates the spectral sensor. Both the spectral sensor and the spatial sensor may access the interior of the process chamber using a common viewport or window, as discussed with respect to FIGS. 9 and 10 above. In some embodiments, an illumination source (e.g., LED) may be activated while capturing the spatial information. For example, the illumination source may illuminate a wall or walls of the interior of the process chamber to visually obtain images of at least the illuminated areas.

At block 1160, the method 1100 may include determining whether the specific locations are clean. In some embodiments, the spatial information may indicate a presence of trace byproducts at the specific locations. For example, images may reveal that portions of a wall that are not clean may have a different color than the known color of the wall without any byproduct or film. In some implementations, contours or boundaries of cleaned areas or films may be identified to determine or estimate a percentage or amount of areas that are clean and a percentage or amount of areas that are not yet clean. In some cases, a ratio or percentage of areas that are clean meeting or exceeding a prescribed threshold amount (e.g., 80%) may indicate that the specific locations are clean. In some implementations, a level of transparency meeting a prescribed threshold (e.g., based on color components, overall shape, edges, brightness, contrast) may indicate that the specific locations are clean.

If the specific locations are clean or sufficiently (above a threshold) clean, the method 1100 may end. If not, the method 1100 may revert back to block 1110.

In some variants, data from the spatial sensor may be captured (block 1150) at the end of spectral data collection (block 1130) irrespective of the indication from spectral information being completed (block 1130). In such cases, collection of spectral information and spatial information may be performed serially or in parallel. This approach may be used to track the rate of clean at certain regions which can be used for optimizing the clean process in addition to collecting spectral data. The rate of clean may further inform whether the specific locations are clean at block 1160.

In some variants, infrared endpoint detection (IR-EPD) may be used in conjunction with the spectral and spatial information.

In some variants, spatial information may be collected first as a primary indication, with spectral information used as secondary, confirmatory information.

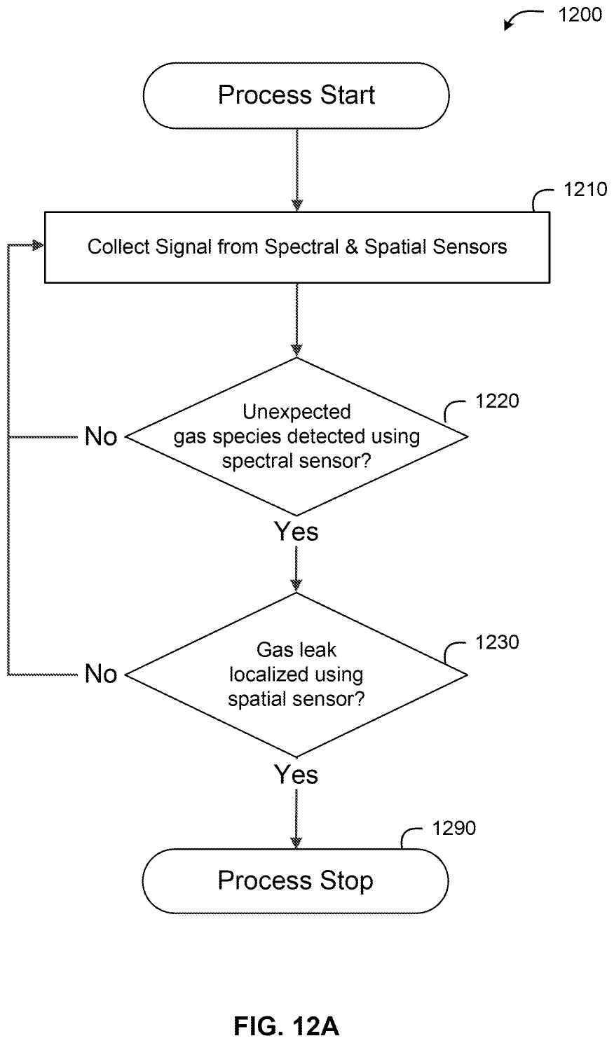

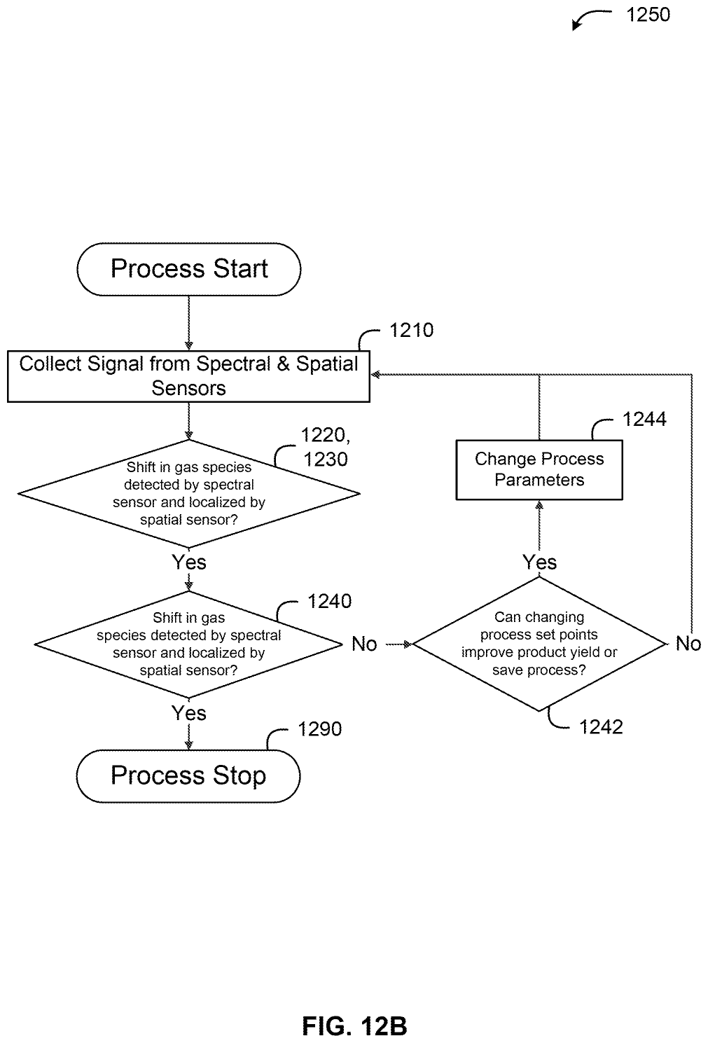

FIGS. 12A and 12B are flow diagrams illustrating methods 1200 and 1250 for determining a presence of unexpected species within a process chamber, according to some embodiments. One or more of the functions of the methods 1200 and 1250 may be performed by or caused by a computerized apparatus or system. Structure for performing the functionality illustrated in one or more of the steps shown in FIGS. 12A and 12B may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system. A subsystem (e.g., 191) may be one example of the computerized apparatus or system. A process chamber may be another example of the computerized apparatus or system. Example components of a process chamber and a controller are illustrated in FIGS. 1A and 1B, and 13, respectively, and described in more detail elsewhere herein.

It should also be noted that the operations of the methods 1200 and 1250 may be performed in any suitable order, not necessarily the order depicted in FIGS. 12A and 12B. Further, the methods 1200 and 1250 may include additional or fewer operations than those depicted in FIGS. 12A and 12B to determine the presence of unexpected species.

At block 1210, the method 1200 may include collecting, during a process (e.g., occurring inside a process chamber), spectral information and spatial information via a spectral sensor and a spatial sensor, respectively. In some embodiments, the spectral sensor may include at least one OES sensor, and the spatial sensor may include at least one camera, both incorporated in a sensor package and installed on fabrication tool, e.g., process chamber. Such sensor package may have access to the interior or exterior of the process chamber and be able to obtain spectral and spatial information through a viewport or window.

In some variants, only spectral information may be collected, and spatial information may be relevant and collected at a later time. For example, the spatial sensor may be triggered to detect spatial information only when the spectral information indicates the presence of an issue (block 1220).

At block 1220, the method 1200 may include determining whether an issue (e.g., a presence of an unexpected gas species) is present. In some embodiments, the determination may be made using the spectral sensor. Consider a scenario in which where the expected plasma has a certain spectral signature and/or emission wavelength, e.g., purple. An external leak involving air entering the process chamber or fabrication system may occur, which may change the spectral signature and/or emission wavelength into, e.g., orange. Such spectral information and/or change in spectral information may be detected via the spectral sensor.

If detected, the method 1200 may proceed to block 1230. If not, the method 1200 may return to block 1210 and continue collecting spectral and/or spatial information.

At block 1230, the method 1200 may include determining whether a gas leak associated with the unexpected gas species is localized using the spatial sensor. The spatial sensor, e.g., camera may visually isolate the issue (e.g., gas leak) identified by the spectral sensor. The gas leak and presence of unexpected gas may be external or internal to the process chamber. Visually isolating the gas leak may allow end user or personnel to be aware of the leak and/or perform Root Cause and Corrective Action (RCCA) to prevent the recurrence of the defect by addressing its cause.

If localized, the method 1200 terminates at block 1290. In some implementations, the termination may occur after or concurrently with RCCA. For example, the fabrication tool or a portion thereof (e.g., a process chamber) may be placed in shutdown mode or at least partly disabled (e.g., certain gas lines).

If not, the method 1200 may return to block 1210 to continue acquiring measurement signals via the spectral and spatial sensors. In some implementations, the method 1200 may return to block 1220 or repeat block 1230 to attempt to localize the gas leak.

In some implementations, however, referring now to FIG. 12B, if localized at block 1230, the method 1200 may proceed to at block 1240, which may include determining whether to terminate the process, rather than terminating the process (block 1290).

If it is determined that the process should not terminate, the method 1200 may proceed to block 1242, which may include determining whether to change a process parameter. Changing the process parameter may bring about beneficial effects for the process, such as improving product yield or saving a process.

If it is determined that changing the process parameter will not bring about beneficial effects, or is unlikely to, then the method 1200 may return to block 1210. In some variants, the method may terminate at block 1290.

If it is determined that changing the process parameter will bring about beneficial effects, or is likely to, then the method 1200 may proceed to block 1244, which may include changing one or more parameters of the process, and the method may return to block 1210 to continue acquiring measurement signals via the spectral and spatial sensors. Examples of process parameters are described elsewhere herein (e.g., power state, reduction or increase in gas, plasma timing, recipe condition).

### Computational and Controller Embodiments

FIG. 13 is a block diagram of an example of the computing device 1300 suitable for use in implementing some embodiments of the present disclosure. For example, device 1300 may be suitable for implementing some or all functions of image analysis logic disclosed herein.

Computing device 1300 may include a bus 1302 that directly or indirectly couples the following devices: memory 1304, one or more central processing units (CPUs) 1306, one or more graphics processing units (GPUs) 1308, a communication interface 1310, input/output (I/O) ports 1312, input/output components 1314, a power supply 1316, and one or more presentation components 1318 (e.g., display(s)). In addition to CPU 1306 and GPU 1308, computing device 1300 may include additional logic devices that are not shown in FIG. 13, such as but not limited to an image signal processor (ISP), a digital signal processor (DSP), an ASIC, an FPGA, or the like.

Although the various blocks of FIG. 13 are shown as connected via the bus 1302 with lines, this is not intended to be limiting and is for clarity only. For example, in some embodiments, a presentation component 1318, such as a display device, may be considered an I/O component 1314 (e.g., if the display is a touch screen). As another example, CPUs 1306 and/or GPUs 1308 may include memory (e.g., the memory 1304 may be representative of a storage device in addition to the memory of the GPUs 1308, the CPUs 1306, and/or other components). In other words, the computing device of FIG. 13 is merely illustrative. Distinction is not made between such categories as “workstation,” “server,” “laptop,” “desktop,” “tablet,” “client device,” “mobile device,” “hand-held device,” “electronic control unit (ECU),” “virtual reality system,” and/or other device or system types, as all are contemplated within the scope of the computing device of FIG. 13.

Bus 1302 may represent one or more busses, such as an address bus, a data bus, a control bus, or a combination thereof. The bus 1302 may include one or more bus types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus.

Memory 1304 may include any of a variety of computer-readable media. The computer-readable media may be any available media that can be accessed by the computing device 1300. The computer-readable media may include both volatile and nonvolatile media, and removable and non-removable media. By way of example, and not limitation, the computer-readable media may comprise computer-storage media and/or communication media.

The computer-storage media may include both volatile and nonvolatile media and/or removable and non-removable media implemented in any method or technology for storage of information such as computer-readable instructions, data structures, program modules, and/or other data types. For example, memory 1304 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 1300. As used herein, computer storage media does not comprise signals per se.

The communication media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the communication media may include wired media such as a wired network or direct-wired connection, and wireless media such as acoustic, RF, infrared and other wireless media. Combinations of any of the above should also be included within the scope of computer-readable media.

CPU(s) 1306 may be configured to execute the computer-readable instructions to control one or more components of the computing device 1300 to perform one or more of the methods and/or processes described herein. CPU(s) 1306 may each include one or more cores (e.g., one, two, four, eight, twenty-eight, seventy-two, etc.) that are capable of handling a multitude of software threads simultaneously. CPU(s) 1306 may include any type of processor and may include different types of processors depending on the type of computing device 1300 implemented (e.g., processors with fewer cores for mobile devices and processors with more cores for servers). For example, depending on the type of computing device 1300, the processor may be an ARM processor implemented using Reduced Instruction Set Computing (RISC) or an x86 processor implemented using Complex Instruction Set Computing (CISC). Computing device 1300 may include one or more CPUs 1306 in addition to one or more microprocessors or supplementary co-processors, such as math co-processors.

GPU(s) 1308 may be used by computing device 1300 to render graphics (e.g., 3D graphics). GPU(s) 1308 may include many (e.g., tens, hundreds, or thousands) of cores that are capable of handling many software threads simultaneously. GPU(s) 1308 may generate pixel data for output images in response to rendering commands (e.g., rendering commands from CPU(s) 1306 received via a host interface). GPU(s) 1308 may include graphics memory, such as display memory, for storing pixel data. The display memory may be included as part of memory 1304. GPU(s) 1308 may include two or more GPUs operating in parallel (e.g., via a link). When combined, each GPU 1308 can generate pixel data for different portions of an output image or for different output images (e.g., a first GPU for a first image and a second GPU for a second image). Each GPU can include its own memory or can share memory with other GPUs.

In examples where the computing device 1300 does not include the GPU(s) 1308, the CPU(s) 1306 may be used to render graphics.

Communication interface 1310 may include one or more receivers, transmitters, and/or transceivers that enable computing device 1300 to communicate with other computing devices via an electronic communication network, included wired and/or wireless communications. Communication interface 1310 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet), low-power wide-area networks (e.g., LoRaWAN, SigFox, etc.), and/or the internet.

I/O ports 1312 may enable the computing device 1300 to be logically coupled to other devices including I/O components 1314, presentation component(s) 1318, and/or other components, some of which may be built in to (e.g., integrated in) computing device 1300. Illustrative I/O components 1314 include a microphone, mouse, keyboard, joystick, track pad, satellite dish, scanner, printer, wireless device, etc. I/O components 1314 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of computing device 1300. Computing device 1300 may be include depth cameras, such as stereoscopic camera systems, infrared camera systems, RGB camera systems, touchscreen technology, and combinations of these, for gesture detection and recognition. Additionally, computing device 1300 may include accelerometers or gyroscopes (e.g., as part of an inertia measurement unit (IMU)) that enable detection of motion. In some examples, the output of the accelerometers or gyroscopes may be used by computing device 1300 to render immersive augmented reality or virtual reality.

Power supply 1316 may include a hard-wired power supply, a battery power supply, or a combination thereof. Power supply 1316 may provide power to computing device 1300 to enable the components of computing device 1300 to operate.

Presentation component(s) 1318 may include a display (e.g., a monitor, a touch screen, a television screen, a heads-up-display (HUD), other display types, or a combination thereof), speakers, and/or other presentation components. Presentation component(s) 1318 may receive data from other components (e.g., GPU(s) 1308, CPU(s) 1306, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

In some implementations, a “controller” (e.g., 190) is part of a system containing a various types of sensors as described herein. Such systems include a fabrication tool with a camera sensor. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The controller may be implemented with or coupled to analysis logic as described above. A controller may be implemented as logic such as electronics having one or more integrated circuits, memory devices, and/or software that receive instructions, issue instructions, control operation, and/or enable sensing operations.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the processing of one or more layers, materials, metals, oxides, silicon, silicon dioxide, surfaces, circuits, and/or dies of a wafer.

A controller may be configured to control or cause control of various components or subparts of the system or systems. The controller, depending on the processing requirements and/or the type of system, may be programmed to control any of the processes that may be used by a fabrication tool during a fabrication operation, including adjusting or maintaining the delivery of processing gases, temperature settings (e.g., heating and/or cooling) including substrate temperature and chamber wall temperature, pressure settings including vacuum settings, plasma settings, RF matching circuit settings, and substrate positional and operation settings, including substrate transfers into and out of a fabrication tool and/or load lock. Process gas parameters include the process gas composition, flow rate, temperature, and/or pressure. Of particular relevance to the disclosed embodiments, controller parameters may relate to plasma generator power, pulse rate, and/or RF frequency.

Process parameters under the control of a controller may be provided in the form of a recipe and may be entered utilizing a user interface. Signals for monitoring the process may be provided by analog and/or digital input connections of the system controller. The signals for controlling the process are output on the analog and digital output connections of the deposition apparatus.

In one example, the instructions for bringing about ignition or maintenance of a plasma are provided in the form of a process recipe. Relevant process recipes may be sequentially arranged, so that at least some instructions for the process can be executed concurrently. In some implementations, instructions for setting one or more plasma parameters may be included in a recipe preceding a plasma ignition process. For example, a first recipe may include instructions for a first time delay, instructions for setting a flow rate of an inert gas (e.g., helium) and/or a reactant gas, and instructions for setting a plasma generator to a first power set point. A second, subsequent recipe may include instructions for a second time delay and instructions for enabling the plasma generator to supply power under a defined set of parameters. A third recipe may include instructions for a third time delay and instructions for disabling the plasma generator. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example. As explained, plasma may be pulsed.

In some embodiments, a controller is configured to control and/or manage the operations of a RF signal generator. In certain implementations, a controller is configured to determine upper and/or lower thresholds for RF signal power to be delivered to a fabrication tool, determining actual (such as real-time) levels of RF signal power delivered to integrated circuit fabrication chamber, RF signal power activation/deactivation times, RF signal on/off duration, duty cycle, operating frequency, and so forth.

As further examples, a controller may be configured to control the timing of various operations, mixing of gases, the pressure in a fabrication tool, the temperature in a fabrication tool, the temperature of a substrate or pedestal, the position of a pedestal, chuck and/or susceptor, and a number of cycles performed on one or more substrates.

A controller may comprise one or more programs or routines for controlling designed subsystems associated with a fabrication tool. Examples of such programs or routines include a substrate positioning program, a process gas control program, a pressure control program, a heater control program, and a plasma control program. A substrate positioning program may include program code for process tool components that are used to load the substrate onto a pedestal and to control the spacing between the substrate and other parts of a fabrication tool. A positioning program may include instructions for moving substrates in and out of the reaction chamber to deposit films on substrates and clean the chamber.

A process gas control program may include code for controlling gas composition and flow rates and for flowing gas into one or more process stations prior to deposition to bring about stabilization of the pressure in the process station. In some implementations, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing numbers of cycles on one or more substrates during the processing of the batch.

A heater control program may include code for controlling the current to a heating unit that is used to heat the substrate. Alternatively, the heater control program may control delivery of a heat transfer gas (such as helium) to the substrate.

In some implementations, there may be a user interface associated with a controller. The user interface may include a display screen, graphical software displays of the apparatus and/or process conditions, and user input devices such as pointing devices, keyboards, touch screens, microphones, etc.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of processing operations, examine a history of past processing operations, examine trends or performance metrics from a plurality of processing operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the processing and/or manufacturing of semiconductor wafers.

The system software may be organized in many different ways that may have different architectures. For example, various chamber component subroutines or control objects may be written to control operation of the chamber components necessary to carry out the deposition processes (and other processes, in some cases) in accordance with the disclosed embodiments.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A manufacturing system comprising:
semiconductor manufacturing equipment;
a plurality of sensors comprising one or more spatial sensors, one or more spectral sensors, and one or more temporal sensors disposed about the semiconductor manufacturing equipment; and
a controller communicatively coupled to the plurality of sensors, the controller configured to cause:
determining a set of signals, from the plurality of sensors, to monitor during a process to be performed by the semiconductor manufacturing equipment;
during the process, obtaining measurements associated with the set of signals from the plurality of sensors; and
determining an indication of a state of the semiconductor manufacturing equipment based on a combination of data generated from the measurements associated with the set of signals.

2. The manufacturing system of claim 1, wherein:
the set of signals are provided by at least two sensor types, the at least two sensor types comprising at least two of (i) at least one of the one or more spatial sensors, (ii) at least one of the one or more spectral sensors, or (iii) at least one of the one or more temporal sensors; and
the at least one of the one or more spatial sensors comprises a camera trained toward an interior of the semiconductor manufacturing equipment, the at least one of the one or more spectral sensors comprises an optical emission spectrometry (OES) sensor configured to detect one or more wavelengths of interest emitted by one or more species generated during the process, and the at least one of the one or more temporal sensors comprises a photodiode configured to detect variations in light intensity that occur over a time period of about 1 millisecond or less.

3. The manufacturing system of claim 2, wherein:
the process to be performed comprises a detection of an unexpected amount of one or more species within an interior of the semiconductor manufacturing equipment; and
the at least two sensor types comprise the one or more spatial sensors and the one or more spectral sensors.

4. The manufacturing system of claim 2, wherein:
the process to be performed comprises an endpoint detection of a chamber clean of an interior of the semiconductor manufacturing equipment; and
the at least two sensor types used concurrently comprises the one or more spatial sensors and the one or more spectral sensors.

5. The manufacturing system of claim 1, wherein the controller further configured to cause modifying a control parameter of the semiconductor manufacturing equipment based on the state of the semiconductor manufacturing equipment.

6. The manufacturing system of claim 1, wherein the combination of data more accurately characterizes the state of the semiconductor manufacturing equipment than a signal from just one of the plurality of sensors.

7. The manufacturing system of claim 1, wherein the controller comprises a machine learning model; and
wherein the determining of the indication of the state of the semiconductor manufacturing equipment comprises performing a classification task or a regression task on at least a portion of the combination of data with the machine learning model to obtain the measurements associated with the set of signals configured to perform.

8. The manufacturing system of claim 1, wherein the one or more spatial sensors comprise one or more cameras or one or more camera arrays, trained toward an interior of the semiconductor manufacturing equipment, and configured to obtain image data relating to the interior before, during, and/or after the process.

9. The manufacturing system of claim 8, further comprising one or more illumination sources configured to provide illumination to the interior of the semiconductor manufacturing equipment;
wherein the illumination enables the one or more cameras or the one or more camera arrays to obtain the image data relating to the interior before, during, and/or after the process.

10. The manufacturing system of claim 1, wherein the one or more spatial sensors comprise one or more cameras or one or more camera arrays, trained toward an interior of the semiconductor manufacturing equipment, and configured to, during the process, obtain data relating to one or more characteristics of plasma present within the interior, the one or more characteristics of the plasma comprising one or more of intensity, boundary, or location of the plasma.

11. The manufacturing system of claim 1, further comprising one or more illumination sources configured to provide one or more pulses of light to at least a portion of an interior of the semiconductor manufacturing equipment, the one or more pulses of light being asynchronous with one or more operations of the one or more spatial sensors.

12. A method for multi-sensor determination of a state of semiconductor equipment, the method comprising:
determining a set of signals, from a plurality of sensors of the semiconductor equipment, to monitor during a process to be performed by the semiconductor equipment, the plurality of sensors comprising at least one spatial sensor, at least one spectral sensor, and at least one temporal sensor;
based on the process to be performed, performing sensor measurements via two or more of (i) the at least one spatial sensor, (ii) the at least one spectral sensor, or (iii) the at least one temporal sensor; and
determining the state of the semiconductor equipment based on the sensor measurements.

13. The method of claim 12, wherein the at least one spatial sensor comprises a camera, the at least one spectral sensor comprises an optical emission spectrometry (OES) sensor, and the at least one temporal sensor comprises a photodiode.

14. The method of claim 12, wherein:
the process to be performed comprises a detection of an unexpected amount of one or more species within an interior of the semiconductor equipment; and
the two or more of (i)-(iii) comprise the at least one spatial sensor and the at least one spectral sensor.

15. The method of claim 12, wherein:
the process to be performed comprises a detection of an endpoint of a chamber clean of an interior of the semiconductor equipment; and
the two or more of (i)-(iii) comprise the at least one spatial sensor and the at least one spectral sensor.

16. The method of claim 12, further comprising modifying a control parameter of the semiconductor equipment based on the state of the semiconductor equipment.

17. The method of claim 12, further comprising using one or more illumination sources of the semiconductor equipment to validate functioning of one or more of (i) the at least one spatial sensor, (ii) the at least one spectral sensor, or (iii) the at least one temporal sensor.

18. The method of claim 12, further comprising using one or more illumination sources to provide pulsed light to at least a portion of an interior of the semiconductor equipment in pulses, the pulsed light being asynchronous with an operation of the at least one spatial sensor.

19. A multi-sensor measurement apparatus with access to an interior of a fabrication tool, the multi-sensor measurement apparatus comprising:
a housing having a principal dimension that is about 10 inches or less;
a spectral sensor within the housing;
a spatial sensor within the housing;
a temporal sensor within the housing; and
a physical interface shaped to allow the housing to attach to a surface of the fabrication tool and receive, through a window of the fabrication tool, electromagnetic signals related to a process performed by the fabrication tool.

20. The multi-sensor measurement apparatus of claim 19, wherein the fabrication tool comprises a process chamber having one or more stations.

21. The multi-sensor measurement apparatus of claim 19, wherein:
the spatial sensor comprises an optical emission spectrometry (OES) sensor configured to obtain spectral information;
the spectral sensor comprises a camera configured to obtain visual information; and
the temporal sensor comprises a photodiode configured to obtain temporal information.

22. The multi-sensor measurement apparatus of claim 21, wherein the multi-sensor measurement apparatus further comprises a communication interface configured to send measurements relating to at least two of the spectral information, the visual information, the temporal information, or a combination thereof.

23. The multi-sensor measurement apparatus of claim 22, wherein:
the process performed by the fabrication tool comprises a detection of an unexpected amount of one or more species within the interior of the fabrication tool; and
the measurements relate to the spectral information and the visual information.

24. The multi-sensor measurement apparatus of claim 22, wherein:
the process performed by the fabrication tool comprises an endpoint detection of a chamber clean of the interior of the fabrication tool; and
the measurements relate to the spectral information and the visual information.

25. The multi-sensor measurement apparatus of claim 19, further comprising an illumination source within the housing, the illumination source configured to provide illumination to at least a portion of an interior of the fabrication tool;
wherein the illumination: enables the spatial sensor to obtain visual information relating to the at least the portion of the interior of the fabrication tool before, during, and/or after the process performed by the fabrication tool; comprises pulses of light that are asynchronous with obtaining visual information relating to the at least the portion of the interior of the fabrication tool; facilitates calibration or validation of one or more of the spectral sensor, the spatial sensor, or the temporal sensor; or a combination thereof.
